(19) United States
(12) Patent Application Publication
(10) Pub. No.: US 2024/0254621 A1
(43) Pub. Date: Aug. 1, 2024

(54) MATERIAL DEPOSITION SYSTEM EQUIPMENT MAINTENANCE

(71) Applicant: Silanna UV Technologies Pte Ltd, Singapore (SG)

(72) Inventor: Petar Atanackovic, Henley Beach South (AU)

(73) Assignee: Silanna UV Technologies Pte Ltd, Singapore (SG)

(21) Appl. No.: 18/604,475

(22) Filed: Mar. 13, 2024

Related U.S. Application Data
(62) Division of application No. 18/056,062, filed on Nov. 16, 2022.

(51) Int. Cl. C23C 16/44; C23C 14/28; C23C 14/54; C30B 23/00; C30B 23/06

(52) U.S. Cl. CPC C23C 16/4411; C23C 14/28; C23C 14/54; C30B 23/005; C30B 23/06

(57) ABSTRACT

A material deposition system comprises a growth chamber configured for a vacuum environment. A fluid circulation panel is inside the growth chamber, spaced apart from an inner surface of the growth chamber and comprising walls around an interior of the fluid circulation panel. An injector pipe is in the interior of the fluid circulation panel and may include a plurality of holes along a length of the injector pipe. A first port may be in communication with the interior of the fluid circulation panel, where the injector pipe is inserted through the first port. A gas heater is configured to supply a heated gas into the interior of the fluid circulation panel to heat the walls of the fluid circulation panel and thereby heat the inner surface of the growth chamber.

### RELATED APPLICATIONS

This application is a divisional of U.S. patent application Ser. No. 18/056,062, filed on Nov. 16, 2022, and entitled “Material Deposition System Equipment Maintenance”; the contents of which are hereby incorporated by reference in full.

### BACKGROUND

In semiconductor fabrication processes, thin film materials are deposited on a planar deposition surface using, for example, a source material in a reaction chamber of a material deposition system. Molecular beam epitaxy (MBE) is one of several methods of depositing single crystal thin films on a substrate. MBE takes place in a high vacuum (HV) or ultra-high vacuum (UHV) (e.g., 10⁻⁶ to 10⁻⁹ Pa; or approximately 10⁻⁸ to 10⁻¹¹ Torr) reaction chamber, where an important aspect of MBE is maintaining low impurity levels of the films deposited. When breaking vacuum or performing preventative maintenance operations on the growth chambers, such as to reload or replace source materials due to depletion or failure, outgassing procedures must be performed to remove contaminants and moisture from the walls of the growth chamber. The outgassing is typically performed using a “bakeout” procedure in which an external oven is constructed around the MBE machine to enclose and heat the MBE machine. This external oven approach is extremely time-consuming, taking several days or even weeks to disconnect supply lines and electrical wiring from the MBE machine, build the oven, ramp the oven up to the necessary high temperatures, perform the bakeout, and then rebuild the MBE. The lengthy downtime for the bakeout process greatly limits the ability of MBE machines to be used at production levels needed for manufacturing.

Some efforts have been made to simplify and reduce the time required for baking an MBE machine. In one example, external heating jackets, such as made of resistive heating tape, have been installed directly on vacuum chambers. However, uniform heating across the chamber can be challenging to achieve with these external heating means. In another example, bakeout lamps inside the reaction chamber have been used. Care must be taken, though, to prevent the lamps from introducing further contamination into the chamber or to prevent contaminants in the chamber from damaging the lamps. In further examples, dry, inert, hot gas may be supplied into the reaction chamber itself to assist in removing water from the internal walls of the chamber. Other approaches aim to reduce downtime of the MBE equipment by isolating components, such as outgassing the source materials in a separate chamber from the main growth chamber. These various methods have been used in combination with each other. Yet even with these techniques, maintenance of material deposition systems such as MBE remains a lengthy and costly process.

### SUMMARY

In some embodiments, a material deposition system comprises a growth chamber configured for a vacuum environment. A fluid circulation panel is inside the growth chamber, spaced apart from an inner surface of the growth chamber and comprising walls around an interior of the fluid circulation panel. A first port is in communication with the interior of the fluid circulation panel. A first gas heater is coupled to the first port to heat and supply a heated gas into the interior of the fluid circulation panel to heat the walls of the fluid circulation panel.

In some embodiments, a method of performing maintenance of a material deposition system comprises evacuating a growth chamber of a material deposition system to a vacuum pressure of at least 1×10⁻⁸ Torr. The material deposition system comprises a growth chamber configured for a vacuum environment; a fluid circulation panel inside the growth chamber and spaced apart from an inner surface of the growth chamber, the fluid circulation panel comprising walls around an interior of the fluid circulation panel; a first port in communication with the interior of the fluid circulation panel; and a first gas heater coupled to the first port to heat and supply a gas into the interior of the fluid circulation panel. The method includes heating the gas with the first gas heater. After the heating of the gas, the gas is supplied into the interior of the fluid circulation panel. The fluid circulation panel is heated, using the gas supplied to the interior of the fluid circulation panel.

In some embodiments, a material deposition system comprises a growth chamber configured for a vacuum environment. A fluid circulation panel is inside the growth chamber, spaced apart from an inner surface of the growth chamber and comprising walls around an interior of the fluid circulation panel. A first port is in communication with the interior of the fluid circulation panel. A first gas heater is coupled to the first port and is configured to supply a heated gas. An injector pipe is inserted through the first port and into the interior of the fluid circulation panel, the injector pipe configured to inject the heated gas at a plurality of locations in the interior of the fluid circulation panel to heat the walls of the fluid circulation panel such that the heated walls of the fluid circulation panel heat the inner surface of the growth chamber.

In some embodiments, a material deposition system comprises a growth chamber configured for a vacuum environment. A fluid circulation panel is inside the growth chamber, spaced apart from an inner surface of the growth chamber and comprising walls around an interior of the fluid circulation panel. An injector pipe is in the interior of the fluid circulation panel, the injector pipe comprising a plurality of holes along a length of the injector pipe. A first gas heater is configured to supply a heated gas through the injector pipe and into the interior of the fluid circulation panel, to heat the walls of the fluid circulation panel such that the heated walls of the fluid circulation panel heat the inner surface of the growth chamber.

### BRIEF DESCRIPTION OF THE DRAWINGS

FIGS. 1A-1D are various views of an example material deposition system that may be used with embodiments of the present disclosure.

FIG. 2 is a schematic of layers of water and other substances on a surface of a growth chamber, as known in the art.

FIG. 3 is a cross-sectional view of an example of a growth chamber being outgassed by an external bake process, as may be used with embodiments of the present disclosure.

FIGS. 4A-4D are various views of an internal bake system for outgassing a material deposition system, such as UHV deposition system, in accordance with some embodiments.

FIGS. 5A-5C are various views of another internal bake system for outgassing a material deposition system, in accordance with some embodiments.

FIGS. 6A-6C are isometric views of injector pipes that may be used with internal bake systems, in accordance with some embodiments.

FIGS. 7A-7C are various views of an internal bake system having multiple gas heaters, in accordance with some embodiments.

FIGS. 8A-8B are views of a fluid circulation panel having a helical rib inside, in accordance with some embodiments.

FIGS. 9A-9C are various views of an internal bake system in which the fluid circulation panel has an aperture aligned with a vacuum pump, in accordance with some embodiments.

FIG. 10 is a cross-sectional view of a heating control arrangement, in accordance with some embodiments.

FIG. 11 is a graph of calculated thermal transfer as a function of gas temperature, in accordance with some embodiments.

FIG. 12 is a schematic of a regenerative gas heating configuration, in accordance with some embodiments.

FIGS. 13A and 13B show examples of resistive heaters for a gas heater, in accordance with some embodiments.

FIG. 14 is a flowchart of a method for outgassing a material deposition system using an internal bake process, in accordance with some embodiments.

FIG. 15 is a block diagram of operation of a control system for an internal bake system, in accordance with some embodiments.

FIG. 16 shows plots of partial pressure and temperature as a function of time during an internal bake process for outgassing a material deposition system, in accordance with some embodiments.

### DETAILED DESCRIPTION

This disclosure describes systems and methods for outgassing material deposition systems after venting, such as venting to atmospheric pressure. Equipment maintenance techniques of the present disclosure apply to material depositions systems with high vacuum or ultra-high vacuum reactors, such as HV or UHV MBE systems. The present techniques involve an “internal bake” procedure which significantly improves preventative maintenance schedules and reduces downtime, thus saving cost and increasing productivity. Embodiments of the disclosure may also be used in conjunction with conventional external oven processes, to help speed up the attainment of internal working temperatures required for water desorption.

Some embodiments uniquely use an existing or modified fluid circulation panel within a growth chamber of material deposition system (e.g., an MBE system) as a heating source. The fluid circulation panel may be a cryopanel (which may also be referred to as a cryoshroud), a source cooling panel or a drip pan. Accordingly, description of heating a cryopanel in this disclosure may also apply to heating other fluid circulation panels, housings, chambers, or vessels that are part of a deposition system, where heating of the other fluid circulation panels can also assist in outgassing of surfaces within the reactor. During the outgassing process, the fluid circulation panel is injected with a heated gas rather than a cooling liquid as during normal operation. The heat produced by the heated gas desorbs species from the walls of the growth chamber as well as the surfaces of the fluid circulation panel. The present systems and techniques can achieve the required heating temperatures inside the growth chamber in a fraction of the time compared to conventional maintenance systems and methods using external ovens, consequently significantly reducing the time to service and maintain material deposition systems such as MBE systems.

The growth chamber of a material deposition system presents a complex shape for external heating to outgas the inner wall and surfaces of the tool. Conventional resistive heater strips applied to the outside chamber walls do not uniformly heat the chamber and result in cold wall regions that can accumulate moisture during outgassing from hot spots. This is further exacerbated by the large tool dimensions. An external oven approach is conventionally the simplest method for achieving uniform bakeout of the entire tool and is a proven method for achieving the prolonged and elevated temperatures (approximately 250° C.) required for initial conditioning or routine maintenance of the inner wall surfaces. Unfortunately, building an external oven requires a strip-down of the tool to a bakeable state (e.g., removing wiring and other components unable to withstand the bakeout temperatures), which is both labor intensive and time consuming.

In contrast to a conventional external bake, an internal bake is disclosed herein that can be used to outgas the chamber after vacuum sealing to enable a fast turnaround to achieve UHV pressures within the chamber. The internal bake is accomplished by heating an internal component within the chamber to desorb species from within the chamber. To achieve this goal, in some cases, components that will be affected by the venting process and areas which can be selectively heated to affect an internal bake are identified. The internal bake techniques of the present disclosure are not necessary for routine chamber openings that involve effusion source refill or source replacement which, if managed strictly, do not require a full bakeout using an external oven.

High vacuum deposition systems and processes throughout this disclosure shall be defined as systems and processes operating at pressures of less than or equal to 5×10⁻⁴ Torr, such as less than or equal to 10⁻⁶ Torr, or from 5×10⁻⁴ Torr to 10⁻¹¹ Torr, or from 10⁻⁵ Torr to 10⁻¹¹ Torr. Embodiments also include use of ultra-high vacuum (UHV) (e.g., approximately 10⁻⁶ to 10⁻⁹ Pa, or 10⁻⁸ to 10⁻¹¹ Torr).

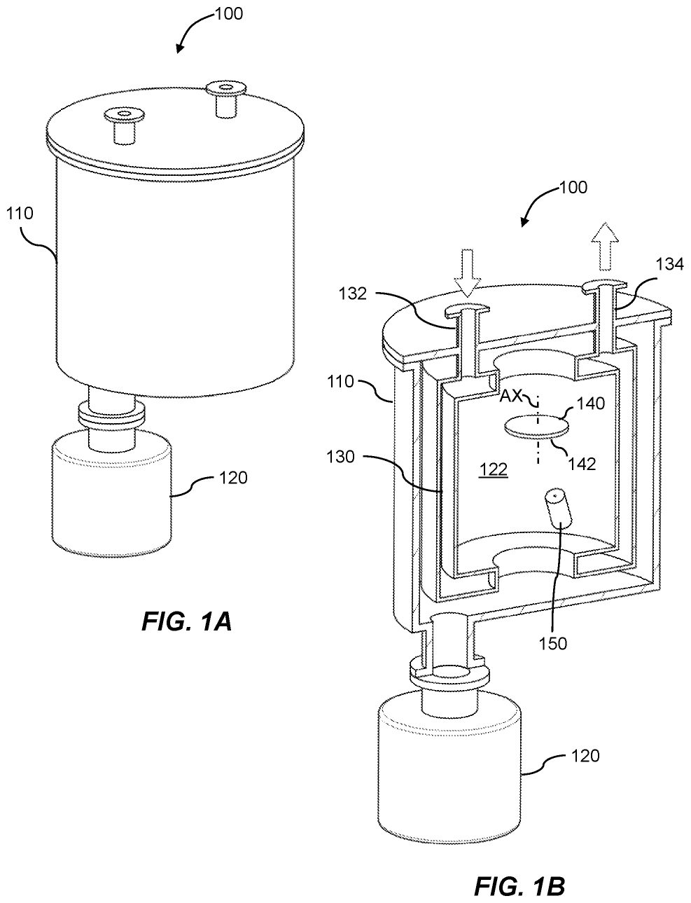

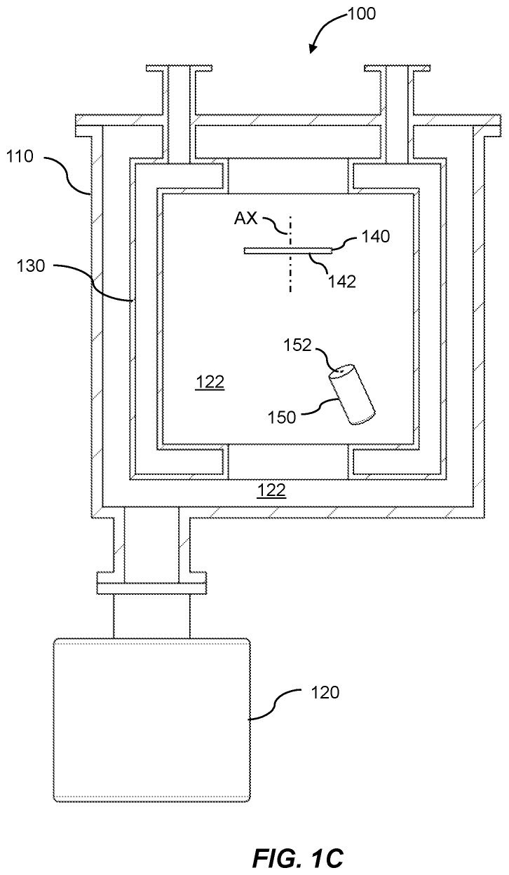

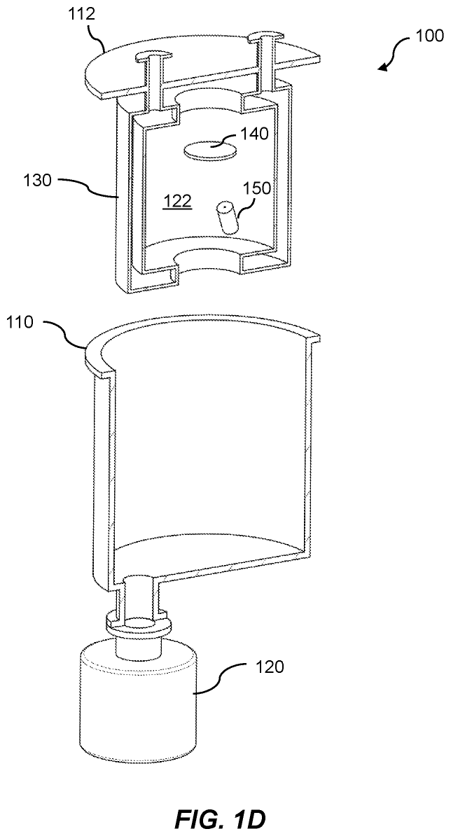

FIGS. 1A-1D are various figurative views of a deposition system 100 (e.g., a UHV deposition system such as MBE) that may be utilized in embodiments of the present disclosure, comprising a growth chamber 110, a vacuum pump 120 and a cryogenic cooling arrangement (i.e., cryopanel 130). FIG. 1A is an isometric view, FIG. 1B shows a cutaway isometric view of growth chamber 110, FIG. 1C is a vertical cross-sectional view similar to FIG. 1B, and FIG. 1D is an exploded view. The figures also show a substrate 140 and a material source 150 that provides material for growing on a film formation surface 142 of substrate 140. In this example, the material source 150 is shown located within cryopanel 130. In other examples, one or more material sources may be coupled to the growth chamber, such as being located outside of the growth chamber with corresponding apertures formed in the growth chamber and cryopanel to allow material to transfer from the material source to the substrate in the deposition process.

The deposition system 100 may be an MBE system, or other type of deposition system such as for metal organic chemical vapor deposition (MOCVD), evaporation, sputtering or etching. A vacuum environment 122 is maintained within the high-vacuum reaction chamber (growth chamber 110) by vacuum pump 120. For example, the vacuum environment 122 may be in the range from about 1×10⁻¹² Torr to about 1×10⁻⁷ Torr, from about 1×10⁻¹ Torr to about 1×10⁻⁹ Torr, or at about 1×10⁻¹¹ Torr to 1×10⁻⁵ Torr. A well-prepared and substantially leak-free reactor has a base pressure and growth pressure (i.e., during deposition) that is directly related to the pumping speed of the reactor and the incident beam pressures generated by the sources.

Material source 150 is arranged with respect to substrate 140 inside of growth chamber 110. The substrate 140 may be any base material on which a film or layer of material may be formed. The substrate 140 can be rotatable around a center axis of rotation AX. The side of the substrate 140 that is facing the material source 150 provides the film formation surface 142. In some cases, deposition system 100 can include a platen with multiple substrates in place of substrate 140. In some cases, deposition system 100 can include more than one material source similar to material source 150.

The formation surface 142 is the target of the material delivered from the material source 150. That is, the formation surface 142 is the side of the substrate 140 on which a film may be formed, such as by epitaxy. Epitaxy refers to the deposition of a crystalline overlayer on a crystalline substrate, where the atomic structure of the overlayer is registered with that of the substrate. In epitaxial growth, crystal orientations of the overlayer and the substrate are aligned such that the atomic structure of the overlayer can register with that of the substrate. The overlayer is called an epitaxial film or epitaxial layer, and sometimes called an epilayer.

The material source 150 may be any source of material (e.g., elemental and pure species) from which a film may be formed on the formation surface 142. For example, the material source 150 may be a Knudsen effusion cell. A typical Knudsen effusion cell includes a shaped crucible (made of high purity pyrolytic boron nitride, fused quartz, tungsten, or graphite), a plurality of resistive heating filaments, a water-cooling system, heat shields to contain the heat within the crucible body, a crucible orifice, and an orifice shutter, none of which are shown but are well known by those skilled in the art. The material source 150 includes an exit aperture 152 (FIG. 1C). In the case of a Knudsen effusion cell, the exit aperture 152 is an opening in the end of the crucible that faces the formation surface 142. As a result of crucible heating, the material (e.g., a liquid) inside the crucible is also heated and material atoms are evaporated (e.g., from the liquid surface). The number of atoms evaporated per unit area (of the liquid surface) per unit of time can be well controlled by controlling the crucible temperature. The evaporant atoms or species are delivered under pressure from the exit aperture 152, travel with a well-defined exit velocity and with a mean free path in excess of the source-to-substrate distance (maintained by the high vacuum level in the reactor), and are directed toward the formation surface 142 where they collide and/or interact with the material of the formation surface 142.

In some configurations not shown, an MBE system such as system 100 may include two growth chambers with preparation chambers coupled to each growth chamber. A load-lock module is used for transferring platens from atmosphere into a vacuum environment that can interface to a UHV module.

In some configurations of system 100, growth and preparation chambers are equipped with substrate heaters employing fully azimuthal rotation. The chambers are actively pumped by closed cycle liquid helium pumps. The total pumping speed of each growth chamber may comprise three pumping systems: (1) He-cryopump; (2) continuous feed upper LN₂ cryoshroud; and (3) turbo pump. Each He-cryopump and turbo pump is isolated from the growth chamber via large diameter vacuum valves. Base pressures for the chambers are 1×10⁻¹¹ Torr for the growth chambers, 1×10⁻¹⁰ Torr for the preparation chambers, and 1×10⁻⁸ to 1×10⁻⁹ Torr for the load-lock chamber.

A main component of an MBE system is the internal liquid nitrogen (LN₂) cryopanel 130 (which may also be referred to in this disclosure as a growth cryopanel, a cryoshroud or cryovessel). During normal operation (i.e., when the MBE is being used to perform deposition), liquid nitrogen is contained within the cryopanel 130. As shown in FIGS. 1B-1C, the walls of the growth chamber 110 are shielded by the cryopanel 130. Liquid nitrogen is pumped into the crypopanel through a port 132, with exhaust being removed through a port 134. The cryopanel 130 traps contaminants in the chamber and also serves as a thermal management system, to help maintain the vacuum levels in the growth chamber.

FIG. 1D is an exploded view of the deposition system 100 shown in FIGS. 1A-1C illustrating that in one example the cryopanel 130 is mounted to the growth chamber lid 112 such that the cryopanel 130 and lid 112 may be removed together. The lid 112 of the growth chamber supports a substrate heater/rotation assembly (not shown) and provides access to supply return bayonets for LN₂ feed of the cryopanel. The cryopanel is mechanically held in place via pedestals attached to the inner chamber walls. Various interface surfaces between components of the UHV deposition system 100, such as between the lid 112 and growth chamber 110, are sealed via conflat knife edge copper gasket technology.

Conventionally, MBE bakeout methods have been performed on stainless steel chambers sealed with opposing conflat knife-edge flanges and compression of an oxygen-free copper (Cu) gasket. All-metal valves are used as a first preference, with large area gate-valves chosen with bankable fluoropolymer elastomer (e.g., VITON™) seals. A mandatory minimum specification for all parts on the metal chamber is the ability to withstand 250° C. temperature baking. The baking process is typically performed using external heaters surrounding the bakeable vacuum chamber that is actively pumped. To aid in thermal efficiency for the external bake process, bakeout panels are formed surrounding the chamber to trap heated air, thereby forming a temporary oven. Uniform heating of the chamber within the oven is necessary to prevent mechanical stress and reduce leaks induced by thermal expansion. Convective stirring of the heated air in the external bake oven is necessary for improving the thermal distribution within the oven as only a finite set of resistive heater elements are used. In some cases, MBE bakeout has been done using localized external contact heating using heater tape. However, in some cases it has been found that localized external contact heating using heater tape is not sufficient to provide the uniform heating necessary of large surface area reactors. The conventional technique of using an external encapsulating oven has been shown to be a reliable and effective method for conditioning complex UHV metal chambers.

Virgin vacuum chambers also require repeated high temperature bakes (e.g., at 250° C.) to fully condition the inner vacuum metal surfaces. The UHV chambers that can be maintained using the systems and methods herein can have inner surfaces that are electropolished which dramatically reduces the total surface area by 5-10× compared to an untreated surface, and thus improves the desorption efficiency of contaminants. Protective coating materials for stainless steel can also be used, however, in some cases have inferior performance to electropolishing and high temperature bake conditioning. Aluminum can also be used in the UHV chambers of the systems and methods described herein due to the stable and non-porous oxide which forms. The chamber walls of the systems and methods described herein can be made from low carbon and high molybdenum content steel (316L-UHV grade) which is a high performing material with a vast historical database available.

In an example reaction chamber, the inner walls are UHV-grade 316 stainless steel which are multiply baked up to 250° C. to condition the inner surfaces to form an in-vacuo stable skin. For example, after conditioning, iron oxides and carbides result which are stable but porous to permeating/diffusing species such as hydrogen and the like. Hydrogen can permeate through the stainless steel from the atmospheric side and can be ever present in the UHV chamber even after extreme baking campaigns. The reduction of hydrogen requires active gettering, which is possible, but not necessary. For comparison, the hydrogen loading in a well-conditioned UHV chamber with base pressure of 1×10⁻¹¹ Torr is typically many orders of magnitude lower partial pressure than an equivalent MOCVD process, and thus offers a potential hydrogen-free environment (e.g., for epitaxy of III-N materials).

After a chamber has been conditioned to form the stable inner surface, the venting procedure can determine the pump-down time and ultimate vacuum possible once re-evacuated. The present methods and systems assume that the chambers have already been conditioned. That is, the present methods and systems are for removing atmospheric contaminants during short chamber openings to aid in achieving rapid recovery of UHV conditions (e.g., at the 1×10⁻¹¹ Torr base level) after the openings.

The majority of high vapor pressure species limiting UHV performance is typically water contaminating the inner vacuum surfaces. The water is introduced via the venting process while breaking vacuum, and during the subsequent time the chamber remains exposed to atmospheric conditions.

In some cases, gross inner chamber contamination during the venting cycle can be mitigated (or minimized) by using water-free and inert gases to pressurize the UHV chamber to atmospheric conditions. Subsequent to venting, the chamber ideally should be continuously flowed with slightly higher than atmospheric pressure inert gas to inhibit atmospheric species from entering the chamber. Excellent results can be obtained using ultra-high pressure (UHP) nitrogen (N₂(g)) gas as the venting feedstock gas. Additionally, it has been empirically found that UHP argon (Ar) gas is as good as or superior to N₂(g) for the first venting step which exposes the inner UHV skin walls. Therefore, in some cases, argon can be utilized as the first venting gas species for UHV chamber processes. Continuous flow of inert N₂(g) can then subsequently be used.

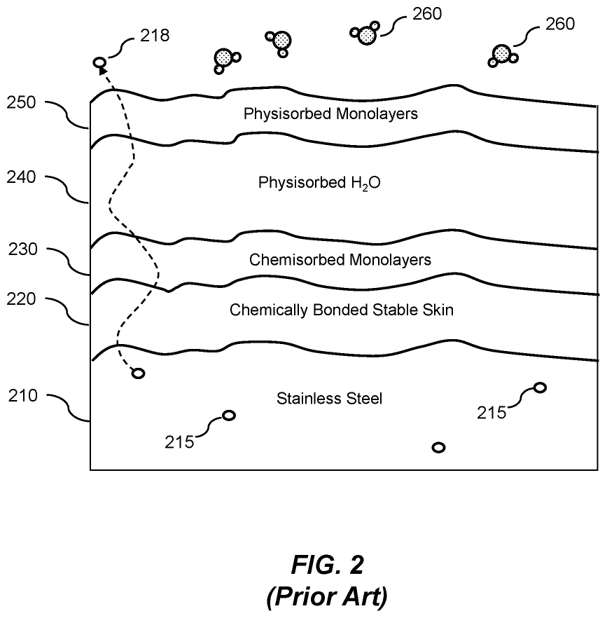

The chemical composition of the UHV stainless steel surface (e.g., stainless steel 316) has been exhaustively investigated, which now enables routine UHV conditions to be achieved. FIG. 2 shows the makeup of an otherwise pristine UHV-grade stainless steel surface 210 (e.g., of a vacuum chamber) that has been conditioned and then re-exposed to atmospheric conditions whereby the gross contamination comprises a water attachment process. The steel surface 210 contains impurities and dissolved gases 215. Outdiffusion of these impurities and gases is indicated by particle 218. On the clean surface 210 of the conditioned steel, is a stable skin 220 of chemically bonded iron-oxides, iron-carbides and iron-nitrides. The stable skin 220 is particularly efficient at chemisorbing one to two monolayers of water, oxygen, hydrogen and nitrogen, illustrated as layer 230. The next layer 240 comprises physisorbed water (H₂O), for example, of approximately 5 to 10 monolayers in thickness. The topmost physisorbed layer 250 is a thin (e.g., 1 to 2 monolayer) film composed of H₂, CO, CO₂ and CH₄.

Each monolayer of water is held together by strong hydrogen bonds with high affinity of electro-positive hydrogen atoms for electro-negative atoms such as oxygen (O). Adsorption takes place by physical adsorption or chemical adsorption. In physical adsorption gas molecules are attracted weakly by Van der Waals forces with binding energies of less than 40 kJ/mol (10 kcal/mol or 0.4 eV). In chemisorption, where actual chemical bonding occurs between the gas molecules and the molecules and atoms on the surface of the vacuum chamber material, these binding energies vary between 80 kJ/mol and 800 kJ/mol (20 to 200 kcal/mol or 0.8 to 8 eV).

A majority of the physisorbed water can be desorbed (water molecules 260) in vacuum from a metal surface by raising the temperature of steel surface 210 above 80° C. (preferably above 100° C.). A portion of the chemisorbed surface water can require temperatures beyond 250° C. to desorb, where further desorption begins at approximately 500-550° C.

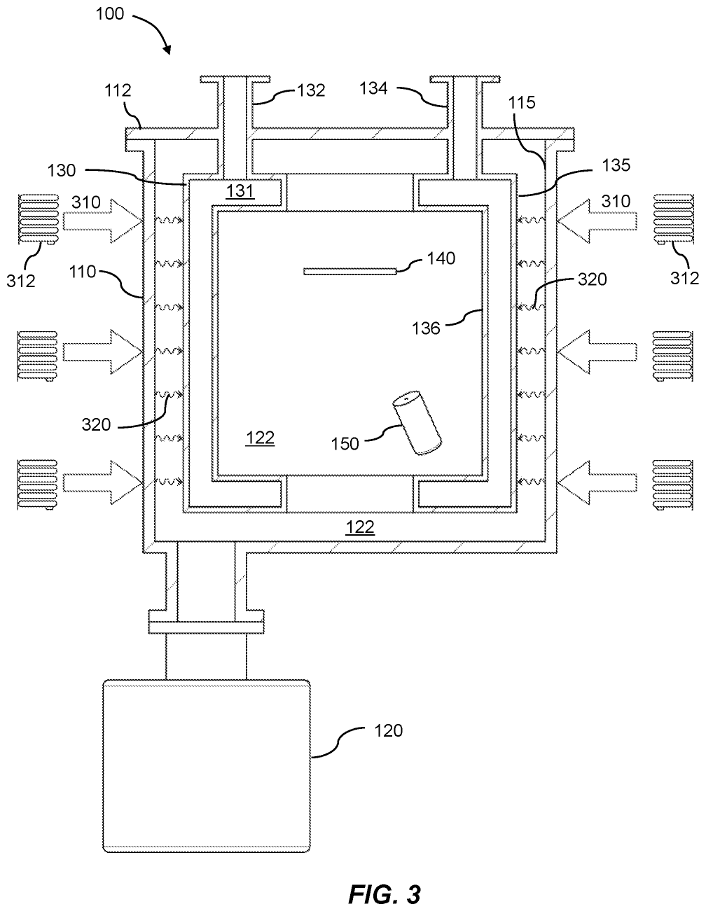

FIG. 3 is a cross sectional view showing the conventional process of outgassing the growth chamber 110 and cryopanel 130 by means of heating the external walls of the growth chamber. This external heating process may be used in conjunction with embodiments of the present disclosure. The large arrows 310 indicate external heat applied by external heaters 312 (e.g., resistive heaters attached to walls of growth chamber 110, or heaters of an external oven) during a conventional bake process. Bakeout is done after the chamber is evacuated using active pump 120, and therefore cryopanel 130 is insulated via vacuum environment 122 from the walls of growth chamber 110. The vacuum-sealed cryopanel vessel has an interior 131 connected to LN₂ fluid ports 132 and 134.

The fundamental construct of the UHV deposition chamber provides conditions for molecular flow of species within the chamber. This means the mean free path of gas species (e.g., N₂ or H₂O) is longer than the dimensions of the chamber and therefore, the cryopumps do not draw or suck molecules toward the entrance aperture of the pumps. Not to be limited by theory, the pump (e.g., pump 120) waits for the arrival of a molecule into the pump and then traps it (e.g., via condensation); that is, the pumping method in UHV conditions is analogous to molecular flypaper. The cryopanel 130 further introduces obstructions for line of sight entry of molecules into the pump 120. This introduces a quasi-random motion of molecules until they are trapped by the pump. The LN₂ cryopanel 130, however, offers line of sight pumping from the interior of the growth chamber (e.g., molecules desorbed from the chamber walls during growth) due to the large cold trap surface area.

The LN₂ cryopanel 130 removes heat from the deposition volume and acts as a line of sight condensing pump. The in-vacuum LN₂ cryopanel walls 136 attain ˜77 K and thus can easily condense metals, oxygen, hydrocarbons, CO and oxygen. The LN₂ cryopanel 130 presents to the growth chamber 110 an extremely large surface area which must be outgassed following a chamber opening. Yet further is the disadvantage during conventional external heating for system baking that thermal transfer 320 from the chamber outer walls to the cryopanel 130 is inefficient across an insulating vacuum. Therefore, the conventional heating method for outgassing the cryopanel 130 is via direct radiative and convective heating of the external chamber walls, with the inner steel walls 115 of growth chamber 110 radiatively heating the outer shell 135 of the LN₂ cryopanel 130. The cryopanel itself is a liquid vessel that is emptied during the conventional bakeout process using external heaters.

The present disclosure utilizes the unique insight that thermal energy transfer to a fluid circulation panel in the material deposition system (e.g., a cryopanel in a molecular beam epitaxy system) can be improved compared to the highly inefficient conventional external oven bakeout process. In embodiments, the outgassing procedure for equipment maintenance of the material deposition system is greatly improved via an internal bake, using the cryopanel or other liquid panel as a housing to serve as a heating source. The present internal bake systems and methods heat the internal walls of the growth chamber more efficiently than a conventional external oven, while also outgassing the surfaces of the cryopanel itself. The present internal bake systems and methods utilize a supply of a hot gas directly into the cryopanel to heat the cryopanel from the inside and to bakeout the cryopanel and interior surfaces of the growth chamber.

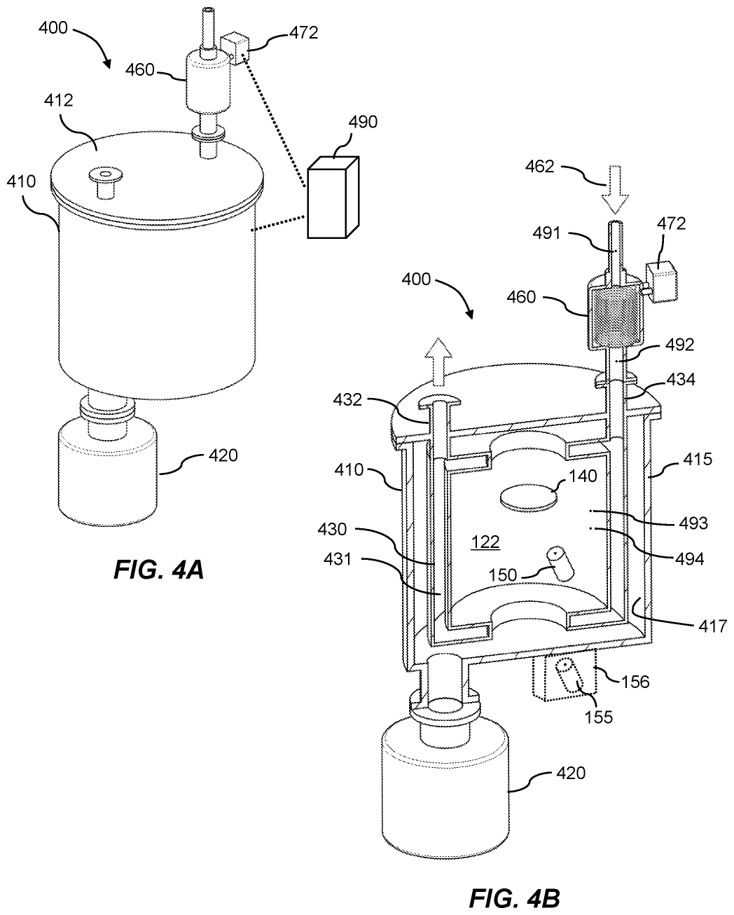

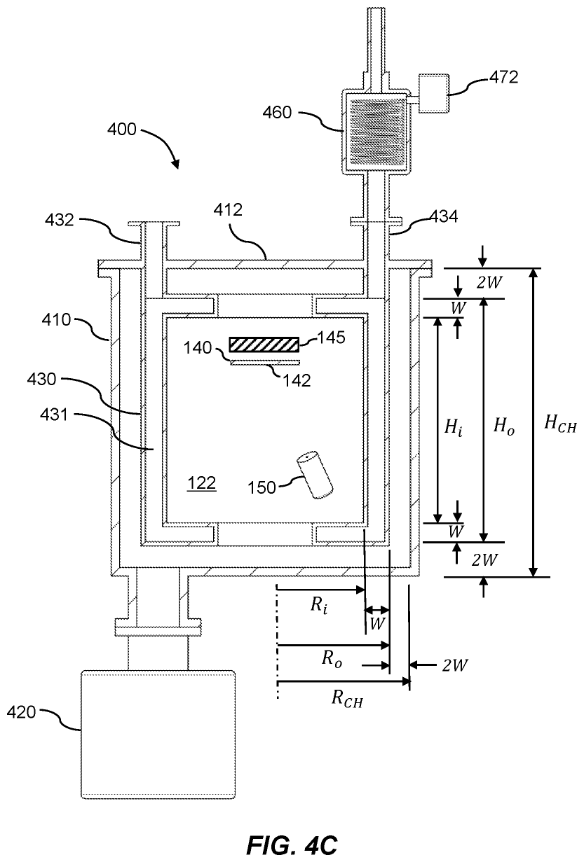

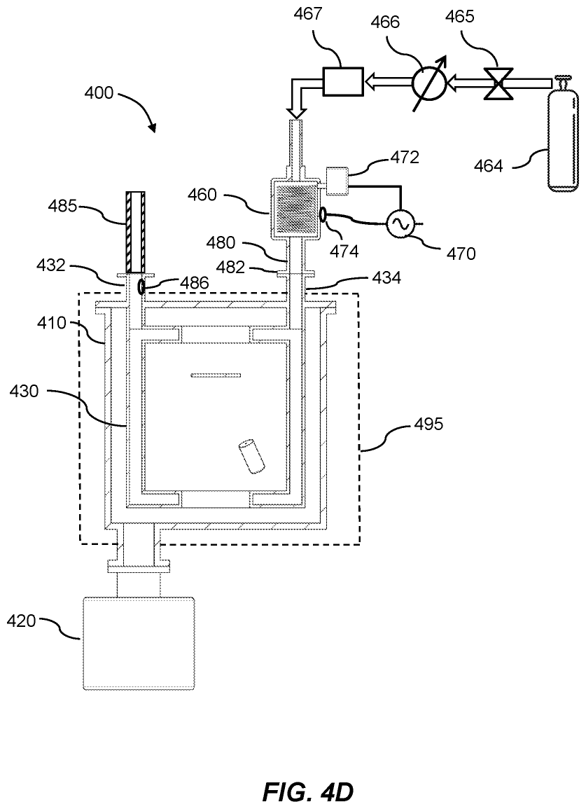

FIGS. 4A-4D are various views of an example system 400 for performing equipment maintenance involving outgassing (e.g., thermally modifying or thermally desorbing) a UHV deposition system, in accordance with embodiments. FIG. 4A is an isometric view, FIG. 4B is a cutaway isometric view of the growth chamber, FIG. 4C is a vertical cross-sectional view, and FIG. 4D is another vertical cross-sectional view with additional components of the system shown. The internal bake system 400 comprises a growth chamber 410, a growth chamber lid 412, and a vacuum pump 420, similar to growth chamber 110, lid 112, and vacuum pump 120 described above. Substrate 140 and material source 150 are also shown inside the growth chamber 410, along with a substrate heater 145 facing the back side of substrate 140, opposite the film formation surface 142. A material source 155 is illustrated in FIG. 4B, providing an example of a material source being located outside the growth chamber (apertures for material from material source 155 into growth chamber 410 are not shown for simplicity). A material source heater 156 that heats material source 155 is schematically shown, coupled to the growth chamber 410.

Cryopanel 430 is inside the growth chamber and spaced apart from an inner surface 417 of the growth chamber, the cryopanel comprising walls around an interior 431 of the cryopanel. Cryopanel 430 is an example of a fluid circulation panel. In other embodiments, another type of fluid circulation panel such as a source cooling panel or a drip pan can be used instead of or in addition to cryopanel 430, where the fluid circulation panel is inside the growth chamber 410 and spaced apart from the inner surface 417 of the growth chamber, the fluid circulation panel comprising walls around an interior of the fluid circulation panel. The interior 431 of the fluid circulation panel is a space or volume enclosed by the walls of the fluid circulation panel. Cryopanel 430 has a gas heater 460 coupled to port 434 to enable the internal bakeout methods of the present disclosure. Cryopanel 430 may be similar to cryopanel 130 or may be modified according to embodiments described herein to enhance the internal heating processes. Port 434 as well as port 432 are in communication with the interior 431 of the cryopanel. The gas heater 460 is configured to heat a gas that is supplied (as indicated by arrow 462) to port 434 of the cryopanel 430. Gas heater 460 is coupled to the port 434 to heat and supply a gas into the interior 431 of the cryopanel. The cryopanel is heated by the gas such that the inner surface 417 of the growth chamber and the walls of the cryopanel are outgassed, removing water and contaminants from the surfaces. The gas is supplied under pressure to cause the heated gas to travel through and heat the cryopanel 430 before exiting port 432. Note that although gas heater 460 is illustrated as being coupled to port 434, in other embodiments gas heater 460 may instead be coupled to port 432, with port 434 serving as an outlet.

In some cases, a proportional-integral-derivative (PID) controller 472 is coupled to gas heater 460 to control the temperature of the gas being heated by heater 460. PID controller 472 is part of a control system 490 (FIG. 4A) that is in communication with sensors and valves of system 400 to monitor and control parameters such as a temperature of the heated gas, flow rate of the heated gas, pressure within the growth chamber, and gas species within the growth chamber. For example, control system 490 may comprise a processor that is in communication with sensors (schematically represented as dots in FIG. 4B) including a flow rate monitor 491 coupled to the gas heater 460, a first temperature sensor 492 coupled to an outlet of the gas heater, a second temperature sensor 493 located in the growth chamber 410, and a pressure sensor 494 located in the growth chamber. The processor is configured to control a flow rate and a temperature of the gas using information from the flow rate monitor, the first temperature sensor, the second temperature sensor, and the pressure sensor.

The cryopanel 430 in conventional use is essentially an isolated cold (LN₂) surface condensing pump that is suspended within a vacuum. The walls 415 of the growth chamber 410 are separated from the cryopanel vessel by UHV and are thus thermally insulated much like a thermos flask. Embodiments disclose unique methods and improvements to conventional deposition systems (e.g., MBE systems), by uniquely enabling the cryopanel 430 to be used as a heating source for performing an internal bake, rather than conventionally using the cryopanel 430 as a cooling source during material deposition processes. Providing proper temperatures, heating rates and chamber pressures that can sufficiently outgas the growth chamber and cryopanel surfaces without causing other contamination is not straightforward to achieve.

FIG. 4C shows a cross-sectional view of the system 400, with dimension parameters labeled for deriving calculating internal bake parameters, in accordance with embodiments. Simplifying the reactor (growth chamber 410) as a cylinder of height H_{CH} and radius R_{CH}, the inner chamber surface area is:

$${A}_{Chamber} = 2 {A}_{lid} + {A}_{wall} = 2 π {R}_{CH} ( {R}_{CH} + {H}_{CH} )$$

The cryopanel 430 has an annular cylindrical shape, presenting both an outer and inner surface of cylinder. If the space between cryovessel walls is W and the outer and inner radii of the cryopanel 430 are Rₒ and Rᵢ respectively, with outer height Hₒ, and inner height Hᵢ then the total surface area presented by the cryopanel is approximately:

$${A}_{Cryo} = {A}_{Cryo}^{outer} + {A}_{Cryo}^{inner} = 2 π [ {R}_{o} ( {R}_{o} + {H}_{o} ) + {R}_{i} ( {R}_{i} + {H}_{i} ) ] .$$

$$Since {R}_{o} = {R}_{i} + W and {H}_{o} = {H}_{i} + 2 W then :$$

$${A}_{Cryo} = 2 π [ 2 {R}_{i} ( {R}_{i} + 2 W + {H}_{i} ) + W ( 3 W + {H}_{i} ) ] .$$

If for simplicity the cryovessel is positioned with a horizontal and vertical gap 2W between the inner chamber wall and the cryopanel outer surface, then R_{CH}=Rᵢ+3W and H_{CH}=_{H}+6W so that:

$$k = \frac{{A}_{cryo}}{{A}_{Chamber}} = \frac{2 {R}_{i} ( {R}_{i} + 2 W + {H}_{i} ) + W ( 3 W + {H}_{i} )}{( {R}_{i} + 3 W ) ( i + {H}_{i} + 9 W )}$$

In an example embodiment, the growth chamber 410 is approximated as a cylinder in which 2Rᵢ=84.5 cm and Hᵢ=72.3 cm, with the approximation of the gap and vessel thickness of W=1.0 cm. This results in k=1.857 which shows that the cryopanel represents approximately 65% of the total surface area within the growth chamber. Using the cryovessel approximated as a cylinder, it is found that A_{Cryo}=99.2 cm²˜1 m². If 12 monolayers (MLs) of water are adsorbed on the vacuum sides of the cryopanel surfaces (i.e., both chemisorbed and physisorbed), then the total volume of water accumulated on the cryopanel is V_{Cryo}[H₂O]=12ML×A_{Cryo}˜5×10⁻⁶ cm³.

FIG. 4D is a schematic of the system 400 having a heated gas injection for outgassing the growth chamber 410 and cryopanel 430 during equipment maintenance. Coupled to the gas heater 460 are an input pressure regulator 466 from house gas 464 (e.g., nitrogen or argon, such as N₂ gas at 5-10 psi), with a valve 465 between the house gas 464 and regulator 466. A flow rate monitor 467 (i.e., a flowmeter) is between the house gas supply 464 and gas heater 460 to measure actual flow rate F of the gas (e.g., nitrogen or argon). PID controller 472 is coupled to gas heater 460 to control heating of the gas being supplied into cryopanel 430. A power supply 470 can be configured to provide a power input of, for example, 240 AC single phase. The power supply 470 is electrically connected to the gas heater 460, the PID controller 472, and a temperature sensor 474 (e.g., a thermocouple) on the gas heater. In embodiments, the gas heater 460 may be connected to the port 434 via a stainless pipe 480 having diameter D=¾″ or larger, with a fitting to the output of the gas heater. The chosen diameter D of the stainless pipe 480 determines the exit velocity v=F/D of the heated gas. In embodiments, a large KF flange 482 can be clamped to the supply port 434 of the LN₂ bayonet for rigid support. The KF flange 482 may be modified or purchased with appropriate fittings to rigidly support the stainless pipe 480 holding up the gas heater. In some embodiments, exit port 432 of the cryopanel may be coupled with a bayonet 485 to prevent user interaction. This bayonet 485 may include a disperser. The air change in the clean room in which the MBE system 400 is located can suffice or a large diameter piping exhaust (e.g., below the floor tiles of the room) may be included.

In some embodiments, a temperature and/or pressure of the cryopanel may also be monitored. For example, in FIG. 4D a sensor 486 may be a temperature sensor (e.g., a thermocouple). The sensor 486 may be inserted into the throat of the exit port 432 as far down as determined to serve as a sufficient monitor of cryopanel temperature. In such an example, a processor of the control system 490 is in communication with the cryopanel temperature sensor 486. The processor may be configured to control the gas heater 460 based on feedback from the sensor 486. The processor may be configured to control the gas heater 460 to limit the cryopanel temperature to a maximum cryopanel temperature, for instance. In another example, the sensor 486 may be a pressure sensor. In this example, the processor is in communication with the pressure sensor in the cryopanel, and the processor may be configured to control the gas heater 460 based on feedback of pressure measurements from the sensor 486. The processor may be configured to alert the control system 490 if the cryopanel is reaching a limit (e.g., in temperature and/or pressure) that may damage the cryopanel, for instance.

One example gas heater 460 which is suitable for heating the cryopanel for the present internal bake techniques is the Watlow STARFLOW™ circulation heater. The Starflow heater is capable of flowing a N₂(g) gas stream to a maximum outlet temperature of 537° C. The 316L stainless steel chamber of the Starflow heater houses a small diameter sheathed element, which allows quick response to both heat-up and cool-down cycles and is unreactive to inert gas feedstock such as nitrogen.

FIG. 4D also shows an external oven 495 that may be used in conjunction with the internal baking techniques of the present disclosure. External oven 495 may be a conventional bakeout oven as described in relation to FIG. 2. In embodiments, methods of outgassing a material deposition system for equipment maintenance may include co-baking the system 400, including growth chamber 410 and cryopanel 430, with an external oven while supplying the heated gas to the cryopanel.

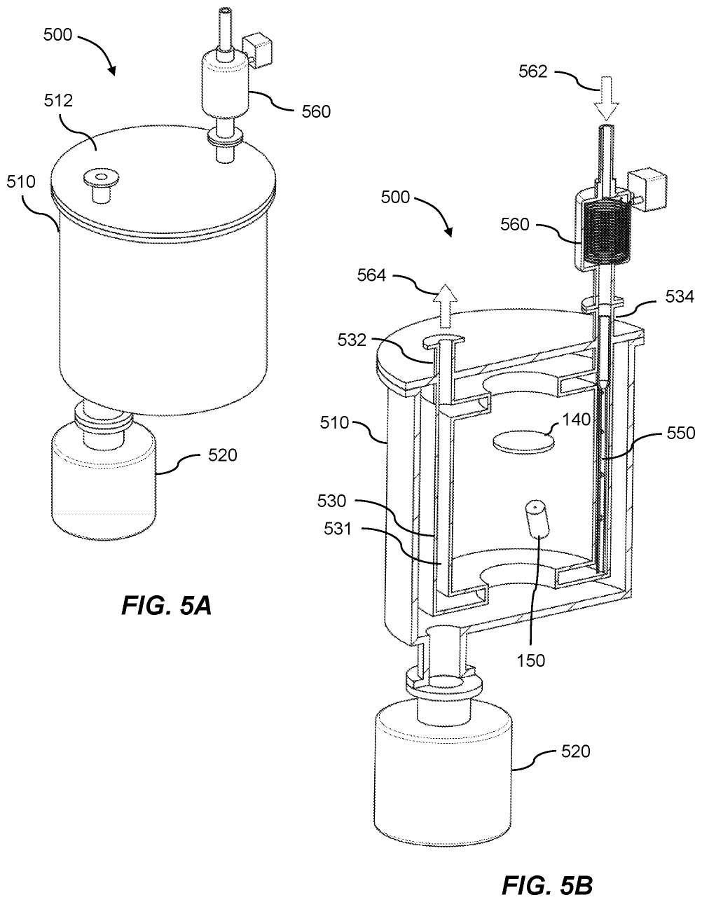

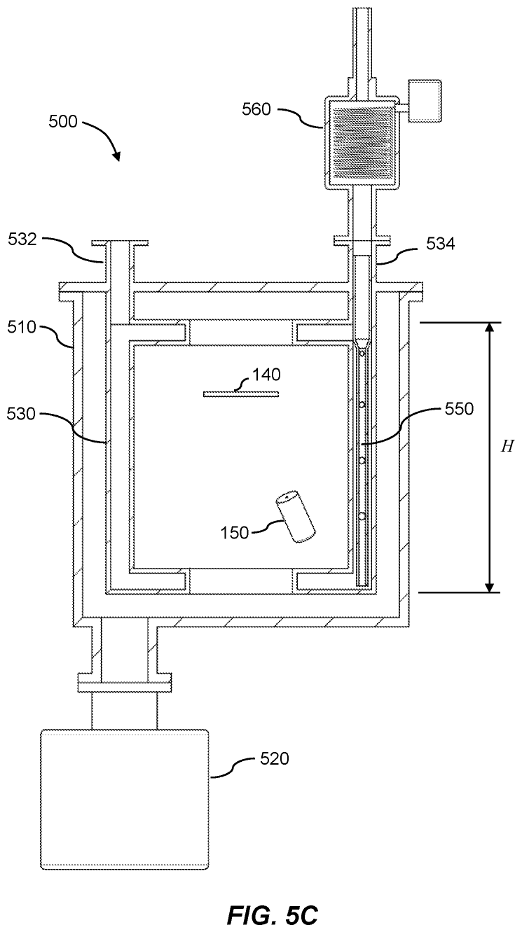

FIGS. 5A-5C are various views of another embodiment for outgassing a UHV deposition system similar to FIGS. 4A-4C, where this embodiment includes an injector pipe extending into the fluid circulation panel (e.g., cryopanel). The injector pipe further assists in uniform heating (and consequently outgassing) of the fluid circulation panel by injecting heated gas at a plurality of locations in the interior of the fluid circulation panel (i.e., distributing the heated gas at multiple/different locations inside the fluid circulation panel). FIG. 5A is an isometric view, FIG. 5B shows a cutaway isometric view of the growth chamber, and FIG. 5C is a vertical cross-sectional view. In FIG. 5A, system 500 for outgassing a material deposition system with an internal bake process comprises a growth chamber 510, a growth chamber lid 512, and a vacuum pump 520. FIG. 5B shows components inside the growth chamber 510 including a cryopanel 530, substrate 140 and material source 150. Cryopanel 530 has a port 532 and a port 534 that are connected to the interior space (interior 531) of cryopanel 530, with a gas heater 560 connected to port 534 in this embodiment. Gas is supplied into gas heater 560 as indicated by arrow 562. The gas is then delivered into interior 531 of cryopanel 530 via first port 534, with exhaust gas leaving the cryopanel through second port 532 as indicated by arrow 564. In other embodiments, the gas heater 560 may be coupled to port 532 instead of port 534, in which case port 532 serves as an inlet to cryopanel 530 while port 534 serves as an outlet.

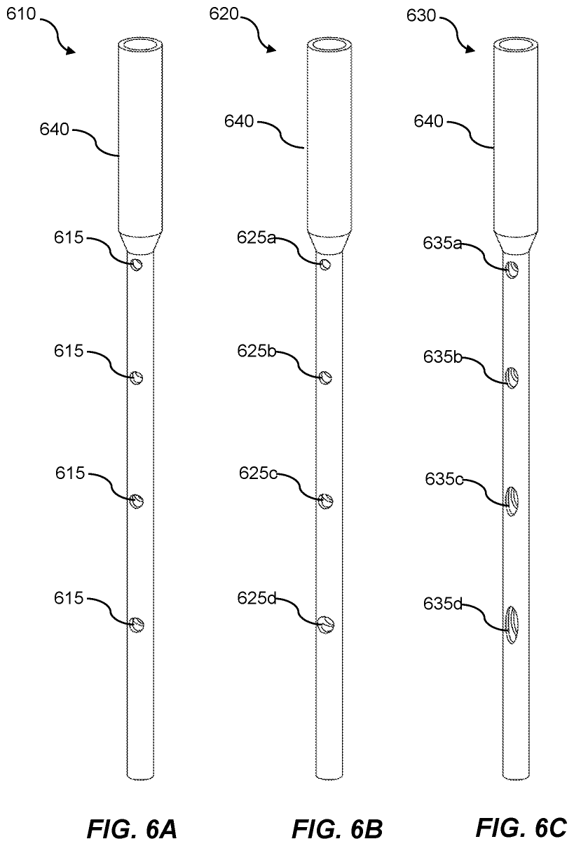

FIGS. 5B and 5C also depict an injector pipe 550 inserted into the interior 531 of the cryopanel through the first port 534. Injector pipe 550 is connected to the supply of heated gas, being inserted through port 534 and extending into the space between the inner and outer walls of the cryopanel 530. Injector pipe 550 is a conduit or tube that includes one or more spaced apart apertures (i.e., holes through a wall of the injector pipe) along its length to distribute gas at different locations within the cryopanel 530 and consequently assist in achieving uniform heating of the cryopanel. The injector pipe 550 may extend along approximately a full height “H” (FIG. 5C) of the cryopanel as shown, or in other embodiments may extend along a portion of the height of the cryopanel. In an example embodiment, injector pipe 550 is a cylindrical ½-inch pipe with holes drilled in it, with a length that extends through approximately the full height of the cryopanel 530. In other embodiments, injector pipe 550 can have other diameters, such as from 0.1 inches to 2 inches, or from 0.25 inches to 0.75 inches. In other embodiments, injector pipe 550 can be shaped like an elongated prism with a non-circular cross-section (e.g., a square or rectangular cross-section) with external cross-section dimensions from 0.1 inches to 2 inches, or from 0.25 inches to 0.75 inches. In some cases, the external cross-section dimensions change over the length of injector pipe 550, for example, injector pipe 550 cross-section can be narrower closer to port 534 and wider father away from port 534. The apertures on injector pipe 550 may have different configurations, as shall be described in relation to FIGS. 6A-6C.

FIGS. 6A, 6B, and 6C are isometric views of embodiments of injector pipes 610, 620, and 630, respectively. Each injector pipe has an entry region 640 with an outer diameter that fits into the inner diameter of port 534 (or port 532), to transport gas into the interior 531 of cryopanel 530. The remaining length of the injector pipe has a plurality of holes (i.e., apertures) through their walls and along a length of the injector pipe, to inject gas at different locations within the cryopanel. In the embodiments shown, there are four holes. However, other numbers of holes may be utilized such as 1 to 20 holes. Also, although the holes are illustrated as being equally spaced from each other, in other embodiments the holes may be spaced apart from each other at varying distances. The configuration of the plurality of holes for the injector pipe will depend on the dimensions and shape of the cryopanel. In some embodiments, holes of the plurality of holes vary in size or shape along the length of the injector pipe.

Injector pipe 610 has uniformly sized and shaped holes 615. Injector pipe 620 has holes 625a-d that have a similar shape to each other but increase in size. For example, hole 625a nearest the entry region 640 is an aperture with a first diameter. Hole 625b is an aperture farther away from entry region 640 and with a larger diameter than hole 625a. Hole 625c has a larger diameter than hole 625b, and hole 625d, which is the most downstream of the holes 625a-d, has the largest diameter. Injector pipe 630 has holes 635a-d that vary in both size and shape. For example, hole 635a nearest the entry region 640 is an aperture that is approximately circular, with a first diameter. The next hole 635b is an elliptical opening that is more elongated than hole 635a, having a major diameter greater than a minor diameter, and with at least the major diameter or the minor diameter being greater than the first diameter of hole 635a. Hole 635c is more elliptical than hole 635b, with its dimensions increased in size compared to hole 635b. The hole 635d, farthest from the entry region 640, is the largest elliptical aperture of the plurality of holes on injector pipe 630.

Variations of the configurations of FIGS. 6A-6C may be utilized to promote uniform heating of the cryopanel, such as adjusting the spacing, number, and/or shapes of the apertures according to the cryopanel dimensions and/or gas flow rates being used. In one example, although the holes of FIGS. 6A-6C are shown as equally spaced, in other embodiments the holes may be unevenly spaced, such as having some holes more concentrated in a particular region. In another example, although four holes are shown, fewer or more holes may be utilized such as between 2 and 10 or between 1 and 20. In some embodiments, the injector tube or pipe (e.g., injector pipe 550, 610, 620 or 630) has unevenly spaced and/or differently shaped/sized holes configured such that it is relatively more difficult for the heated gas to escape injector tube close to port 534, and such that it is relatively easier for the heated gas to escape injector pipe 550 farther from port 534. Such an injector pipe 550 can advantageously enable the flow from each of the holes in injector pipe 550 to be more uniform to one another compared to the case where all the holes are the same (e.g., as shown in FIG. 6A). It will be understood that while the cryopanel depicted in the various embodiments is essentially of a cylindrical configuration, in other deposition systems the cryopanel may have a different profile or configuration which can also depend on the shape and configuration of the growth chamber. The shape and configuration of the growth chamber can also vary depending on requirements of the deposition processes being performed by the equipment.

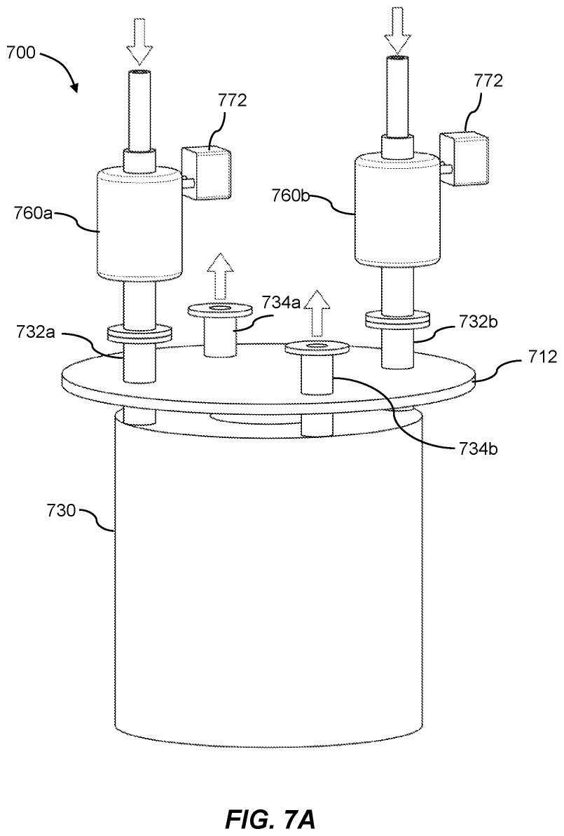

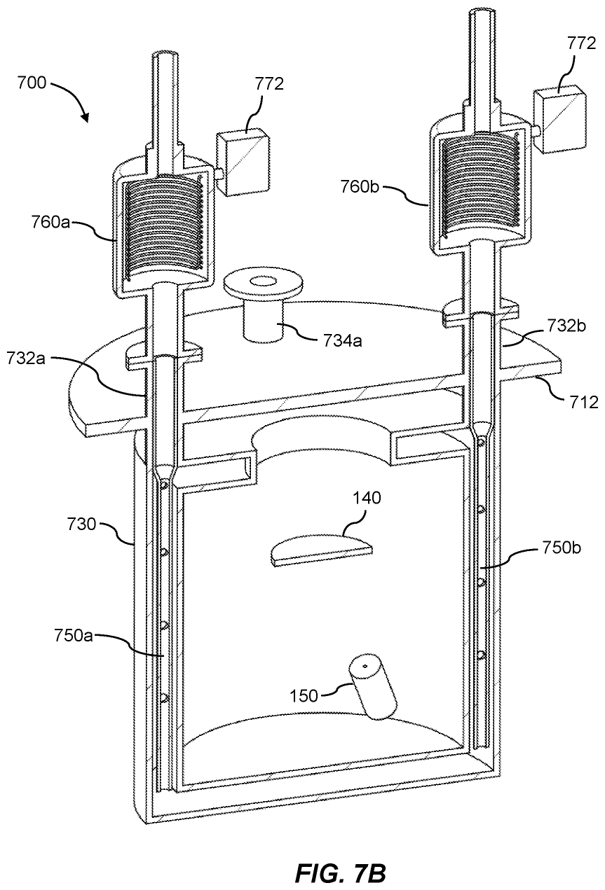

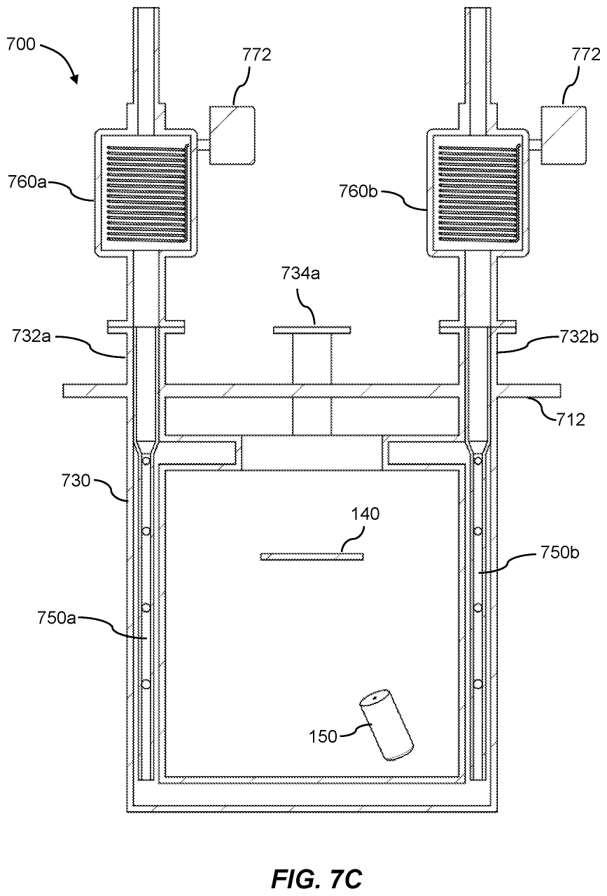

FIGS. 7A-7C are various views of a system 700 for outgassing a UHV material deposition system in accordance with embodiments, in which multiple sources of heated gas and associated outlets are incorporated to promote uniform heating (and outgassing) of cryopanel 730 and a growth chamber (not shown in these figures). In some embodiments the number of gas inlets may be the same as the number of outlets, although in various embodiments it is not necessary for the number of outlets to match the number of inlets. The embodiments of FIGS. 7A-7C may be utilized with or without the injector pipes of FIGS. 5A-5C and FIGS. 6A-6C. For example, none, some, or all the gas inlets may be coupled with an injector pipe.

FIG. 7A is an isometric view of system 700 having two inlet ports 732a and 732b and two outlet ports 734a and 734b coupled to lid 712. The inlet ports 732a-b can be seen extending into the cryopanel 730 on the underside of lid 712. Gas heaters 760a and 760b are coupled to inlet ports 732a and 732b, respectively. Gas heater 760a is a first gas heater coupled to first port 732a, and gas heater 760b is a second gas heater coupled to second port 732b, where first port 732a and second port 734b are in communication with the interior of the cryopanel. Outlet ports 734a and 734b enable gas to flow out of the system 700. Each gas heater 760a-b has a PID controller 772 coupled to it, to control the heating of the gas passing through the gas heaters 760a-b. Operation of PID controller 772 is as described in relation to PID controller 472 above.

Although the inlet and outlet ports are shown as equally spaced and in an alternating arrangement around the lid 712 in this embodiment, other configurations are possible such as having uneven spacing between ports and/or having a different number of inlet ports than outlet ports. Gas heater 760a is positioned diametrically opposite to gas heater 760b in this embodiment, but the multiple gas heaters can have different positions relative to each other in other embodiments (e.g., positioned less than 180° apart from each other radially).

FIG. 7B is a cutaway isometric view of the system 700, and FIG. 7C is a vertical cross-sectional view. In these figures, an injector pipe 750a extends from inlet port 732a, and an injector pipe 750b extends from inlet port 732b. Injector pipes 750a-b may take the form of any the configurations described in FIGS. 6A-6C. Injector pipe 750a may be identical to injector pipe 750b or may have a different configuration from injector pipe 750b.

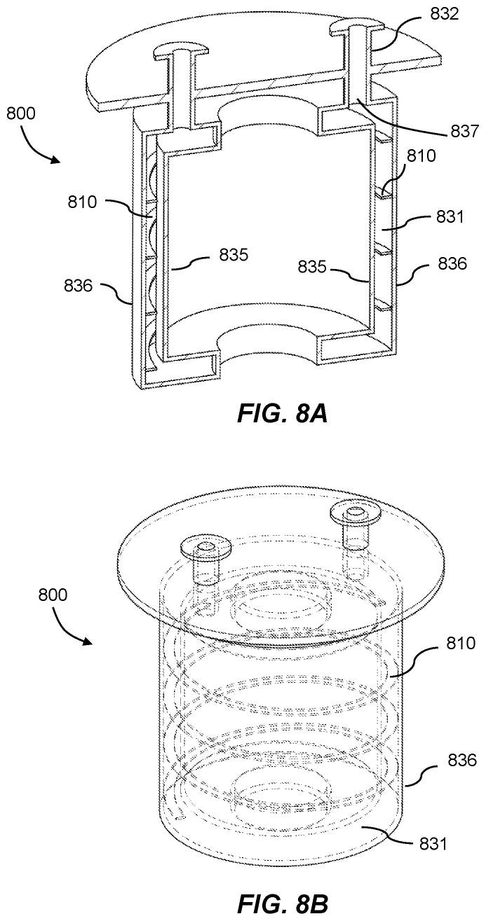

FIGS. 8A-8B show isometric cutaway and external views, respectively, of a cryopanel 800 adapted to promote uniform heating, in accordance with embodiments. In this example, a downwardly extending helical rib 810 is included in the annular cylindrical shaped interior 831, which is the space between inner wall 835 and outer wall 836 of the cryopanel 800. The helical rib 810 is a surface that extends laterally across the width of interior 831, where the helical rib 810 can extend partially across the width as illustrated or fully across the width. The helical rib 810 directs gas supplied through port 832 in a spiral fashion around the cylindrical interior 831 of cryopanel 800. The helical path helps to distribute the heated gas around the circumference and along the height of the cryopanel 800, rather than having heat being more concentrated in the region 837 near or directly below the end of port 832 (at the entrance to the interior 831 of cryopanel 800). In the illustrated example the helical rib is continuous, but in other examples the helical rib can be discontinuous (e.g., the rib having gaps or spaces along its helical path).

In further examples, the cryopanels (or other fluid circulation panels) of the present disclosure may have ribs (which may also be referred to as protrusions, beams, and the like) of different configurations. For instance, the ribs may extend along only a portion of the height or circumference of the cryopanel. As another example, if multiple gas heaters or one or more injector tubes are being used, the ribs may be positioned to receive flow from the inlet port associated with each gas heater and/or from the aperture(s) along the length of the injector tube.

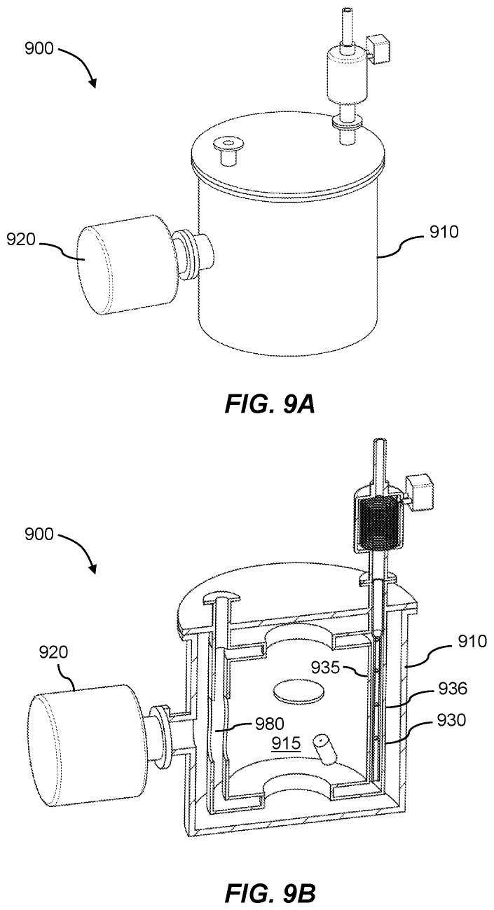

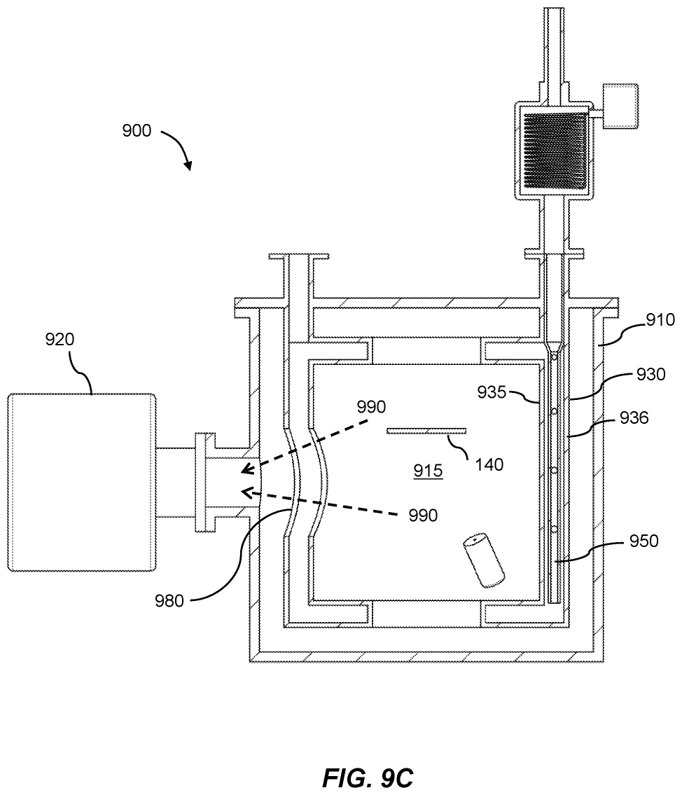

FIGS. 9A-9C are various views of a system 900 for outgassing a UHV material deposition system, in accordance with embodiments. FIG. 9A is an isometric view, FIG. 9B is a cutaway isometric view, and FIG. 9C is a vertical cross-sectional view. In these figures, a vacuum pump 920 is coupled to and positioned on a side (circumferential) wall of growth chamber 910 rather than on a bottom surface of growth chamber 910 as in previous embodiments. The vacuum pump 920 is aligned with an aperture 980 through the walls of cryopanel 930 to expose a central region 915 of the growth chamber 910 and an inner wall 935 of the cryopanel to the vacuum pump 920. The aperture 980 is a cutout, such as a circular cutout, through at least one of the walls of the cryopanel 930. In this embodiment, the aperture 980 is an opening through the inner wall 935 and outer wall 936 of the cryopanel to create a path from exterior of the cryopanel 930 to the central region 915 surrounded by the inner walls 935 of the cryopanel. The vacuum pump 920 is aligned with the aperture 980 such that the vacuum pump 920 has a “line of sight” to central region 915 of the growth chamber 910, the central region 915 being surrounded by the cryopanel 930. This configuration allows for line of sight pumping with respect to the inner wall 935 of the cryopanel 930, which is the most critical surface to be outgassed (compared to the inner surface of the growth chamber) since inner wall 935 is closest to the substrate 140. For pressure ranges of 1×10⁻⁴ to 1×10⁻¹² Torr, particles/molecules will have a long mean free path and thus will interact with the first surface on their path. Accordingly, in order to physically remove material from the interior surfaces (e.g., outgassing substances from the inner wall 935 of cryopanel 930), having a line of sight into this central region 915 will minimize wall interactions before the particle/molecule is physically removed by the vacuum pump 920. Example line of sight paths 990 are illustrated by dashed line arrows in FIG. 9C.

Although FIGS. 9B and 9C are shown with a single injection pipe 950, other components as disclosed herein for promoting uniform heating within the cryopanel (e.g., multiple injection tubes or a helical rib) may be utilized with the line of sight system 900.

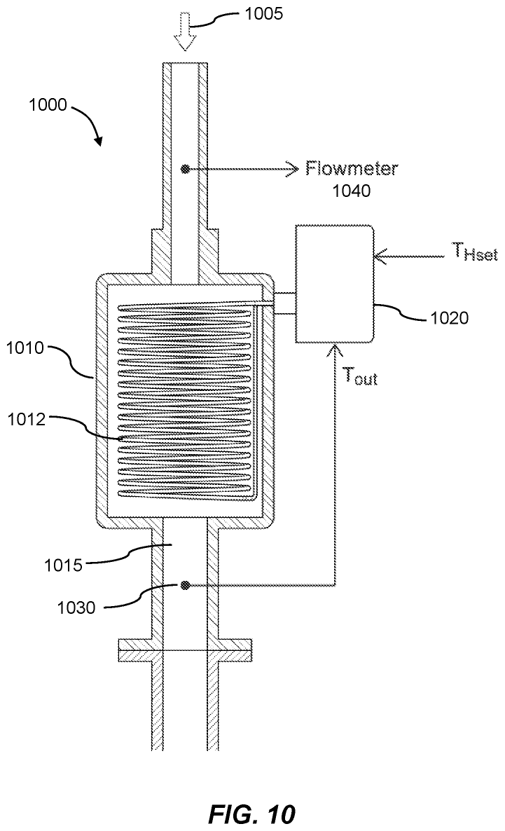

FIG. 10 is a cross-sectional schematic of a heating control arrangement 1000 for heating a gas 1005 that is supplied to the cryopanel. The heating control arrangement 1000 may be part of control system 490 (FIG. 4A) for the material deposition systems disclosed herein. Heating control arrangement 1000 shows a gas heater 1010 having a resistive heating element 1012. The resistive heating element 1012 is connected to a PID controller 1020. In one example, the temperature of the resistive heating element 1012 (e.g., a coil) is adjusted by using PID controller 1020 to vary the electrical current to the resistive heating element 1012, based on a set temperature T_{Hset} and a measured output temperature Tₒᵤₜ. In this example, a temperature sensor 1030 is positioned at outlet 1015 (i.e., outlet end or output end) of the gas heater 1010 to measure Tₒᵤₜ. The temperature sensor 1030 may be, for example, a thermocouple. In other examples, the temperature Tₒᵤₜ may be measured within the cryopanel, or at the outlet of the cryopanel (i.e., an outlet port) or may comprise a combination of temperature sensors at multiple locations. A mass flow controller (not shown) may be included to control the flow rate of the gas 1005 as measured by flow rate monitor 1040 (flowmeter). The flow rate may be varied in accordance with the desired thermal transfer of heat from the heated gas to the cryopanel.

Embodiments involve supplying heated gas into the cryopanel to use the cryopanel as a heating source during outgassing, rather than using the cryopanel as a cooling source (filled with LN₂) during normal operation of the MBE system (i.e., during material deposition on a substrate). The surface area for the present application of outgassing the LN₂ cryopanel requires substantially higher heated N₂(g) flow and gas temperature than conventional applications to transfer sufficient heat from the gas to the cryopanel steel surface, thus presenting new challenges that are not straightforward from the known applications.

The power Q_{Cryo} required in units of Watts/hour to raise the cryopanel temperature by an amount ΔT, such as from either 0° C. or room temperature to a required operating temperature of, for example, 125° C. is calculated via:

$${Q}_{Cryo} = {M}_{Cryo} \cdot {C}_{p} \cdot Δ T$$

where the specific heat of stainless steel is taken as Cp=502 J/(kg·K) and the total mass M_{Cryo}=w·A_{Cryo} using a steel thickness of w=0.25″=6.3 mm.

The total power required to elevate the mass of the steel cryopanel to the desired outgassing temperature can now be used to ascertain whether the gas heater can provide the desired power. To obtain this estimate, the coefficient of thermal transfer β needs to be calculated.

The temperature ramp on the cryopanel can be programmed indirectly via monitoring a temperature sensor (e.g., thermocouple) inserted into an exit port on the tool at a temperature ramp rate of, for example, ≤5° C./minute, such as between 1° C./minute to 5° C./minute, to limit thermal stress.

Because the cryopanel is insulated from the chamber walls via a high vacuum, radiative losses will be the majority heat loss path. The relatively low temperatures required to desorb water in vacuo will, however, result in small blackbody loss and can be neglected. The injected heated gas (e.g., N₂(g)) will ideally undergo turbulent flow in the pressure/flow regime anticipated, with Reynolds number

$$Re = \frac{ρ uL}{μ}$$

where Re=Reynolds number, ρ=density of the fluid, u=flow speed, L=characteristic linear dimension, and μ=dynamic viscosity of the fluid.

Pressurization of the cryopanel in the present disclosure is to be avoided to reduce unnecessary stress on the complex and large number of weldments comprising the cryopanel. That is, the pressure within the cryopanel should be limited to a safe value to mitigate the risk of creating UHV scale leaks at weld locations of the panel. Open ended gas flow may be sufficient to ensure the cryopanel does not pressurize beyond approximately 5 psi (i.e., the exit LN₂ port is to be left open). The incident actual flow rate into the gas heater can be used to determine the exit velocity v_{N2} from the tube diameter D connected to the gas heater outlet and inserted into the cryopanel input port.

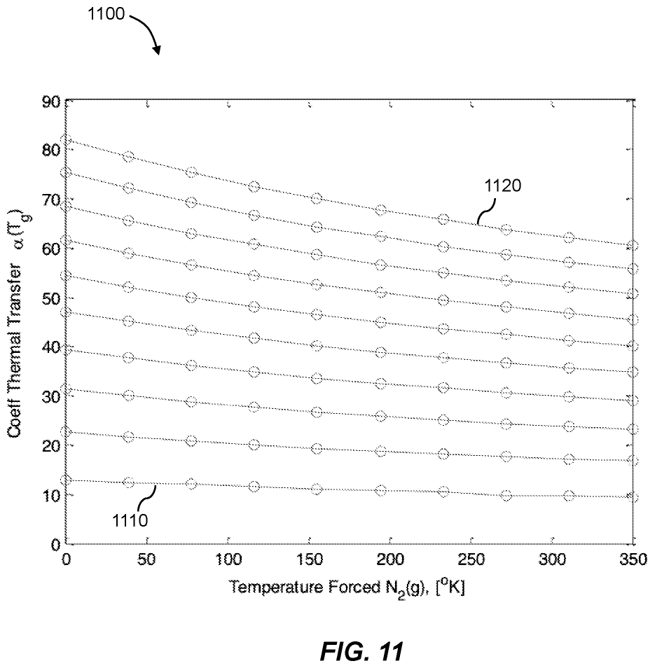

The thermal transfer coefficient β_{N2} of heated nitrogen gas as a function of temperature is calculated using gas kinetics modeled via MATLAB in FIG. 11. Graph 1100 shows the coefficient of thermal transfer α(T_{g}) for pure nitrogen gas versus the gas temperature relative to a metal plate held at 273° K. The curves represent calculations at different gas velocities, where the lowest curve 1110 is for v_{N2}=0.1 m/s, and the topmost curve 1120 is for v_{N2}=50 m/s. The graph 1100 shows that as the temperature of the gas increases, the coefficient of thermal transfer decreases. That is, by increasing the flow rate of heated gas from the outlet 1015 of FIG. 10, there will be a higher transfer of heat to the walls of the cryopanel which will saturate at some level. As can be seen in the graph 1100 of FIG. 11, there will be some optimal gas residence time in the cryopanel to create a given target cryopanel temperature for a given input gas temperature. This modeling indicates that the internal bakeout process can be performed with parameters (e.g., gas velocities and temperatures) that are reasonable and practical to achieve.

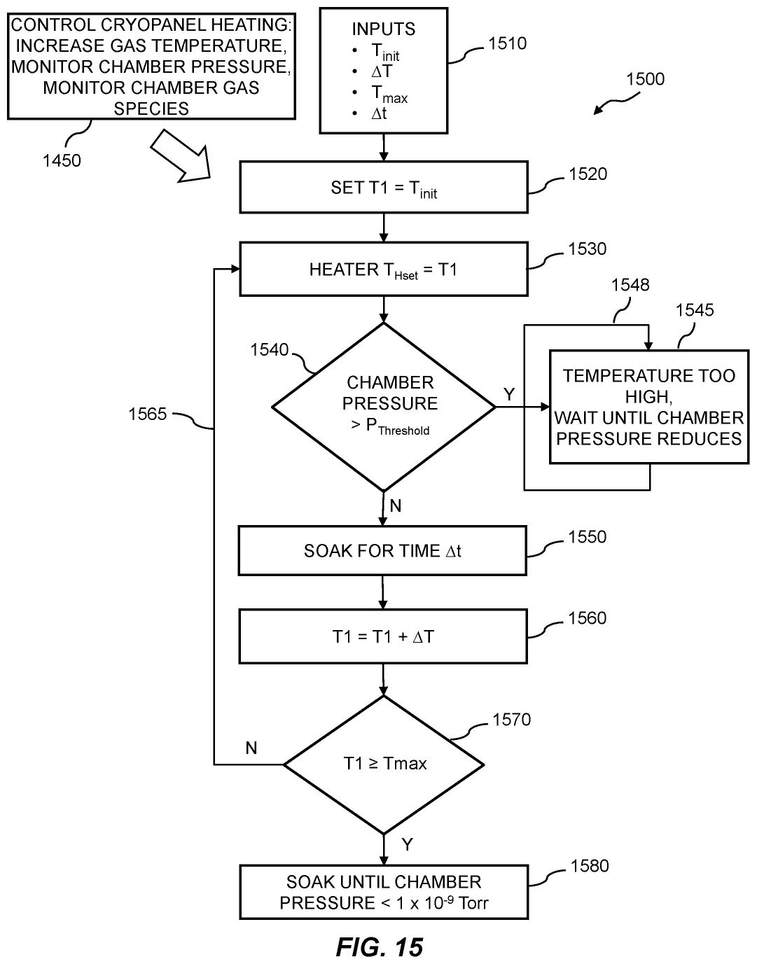

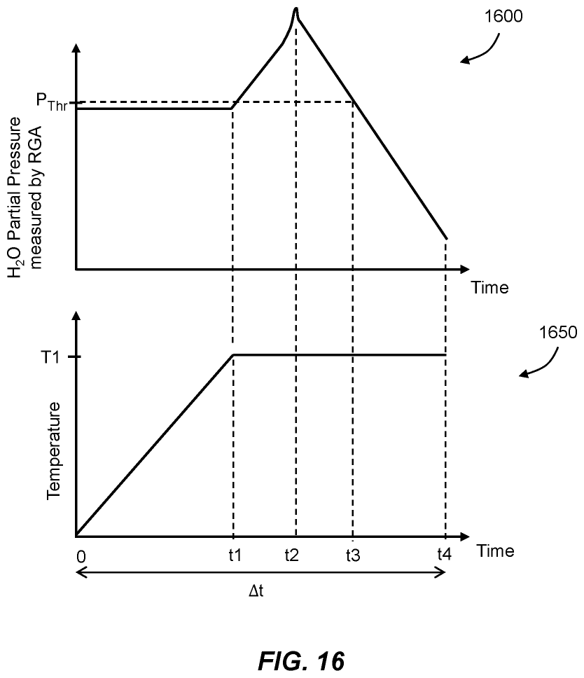

In one example, the input flow rate of heated gas (e.g., nitrogen) into the fluid circulation panel (e.g., cryopanel) is in the range of 10-1000 liters per minute depending on the nitrogen gas temperature, cross-sectional area to be heated and/or fluid circulation characteristics of the cryopanel, and more generally the required thermal inertia to heat the cryopanel. In one example, for a 4 inch diameter substrate deposition chamber (i.e., growth chamber, reaction chamber) with an integrated cryopanel (e.g., see FIGS. 1A-1D), the heating arrangement can be configured to supply heated nitrogen gas having a temperature between 100-300 degrees Celsius and a flow rate between 50-200 liters/minute to heat the cryopanel for 1-5 hours and attain a set point temperature (i.e., target temperature) of the cryopanel ranging between 100-200° C., with the temperature ramp managed in accordance with the pumping capacity of the chamber (see FIGS. 15 and 16 below). In another example, heated gas at a target gas temperature of approximately 150° C. is supplied at a flow rate of approximately 100 liters/minute in order to achieve a heating rate at greater than 3° C./min. This arrangement requires electrical power for the gas heater of approximately 200-500 Watts.

It is understood that higher gas flow rates will require more heater power to achieve a desired heated gas temperature that can be transferred to the cryopanel. It is also understood that the ramp rate may also require management in accordance with the thermomechanical stress limitations of the system.

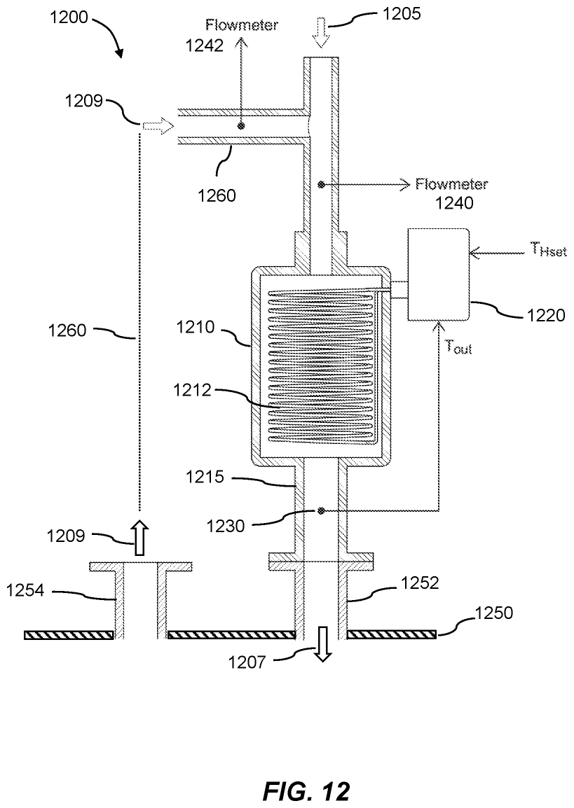

FIG. 12 is a figurative view of a heating control arrangement 1200 comprising a regenerative arrangement where heated gas having already traversed the cryopanel is reheated. Similar to the components of FIG. 10, in FIG. 12 a gas 1205 (e.g., N₂(g)) is input into a gas heater 1210 having a resistive heating element 1212. The resistive heating element 1212 is connected to a PID controller 1220. The temperature of the resistive heating element 1212 is controlled by varying the electrical current to the resistive heating element 1212 in accordance with PID controller 1220, based on a set temperature T_{Hset} and an output temperature Tₒᵤₜ. In the embodiment shown, Tₒᵤₜ is measured by a temperature sensor 1230 positioned at outlet 1215 (i.e., outlet end) of the gas heater 1210. A mass flow controller (not shown) may be included to control the flow rate of the gas 1205 as measured by a first flowmeter 1240 in the inlet path to gas heater 1210. The flow rate may be varied in accordance with the desired thermal transfer of heat from the heated gas to the cryopanel. The heated gas 1207 that is output from the gas heater 1210 enters the cryopanel 1250 at inlet port 1252 and exits at outlet port 1254. The exhaust gas 1209 from outlet port 1254 is recirculated via conduits 1260 to be input again into gas heater 1210, in combination with gas 1205 that is supplied from an external source (e.g., house gas 464 of FIG. 4D). This regenerative arrangement of FIG. 12 advantageously utilizes the already heated exhaust gas 1209 to more efficiently provide heated gas 1207 into cryopanel 1250. A second flowmeter 1242 in the return path of exhaust gas 1209 may also be included to help regulate the flow rates being supplied into gas heater 1210.

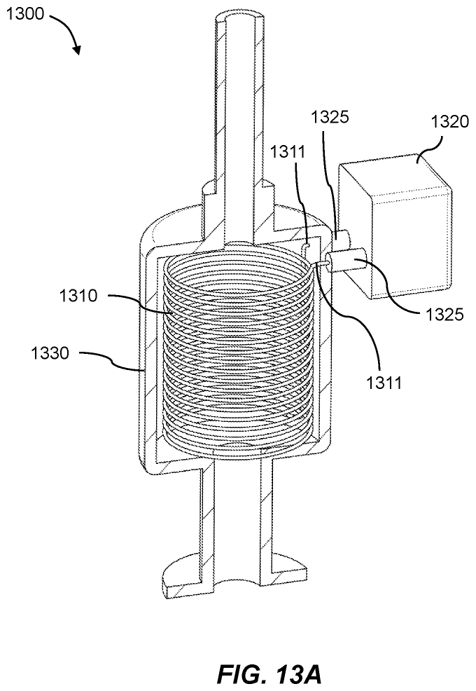

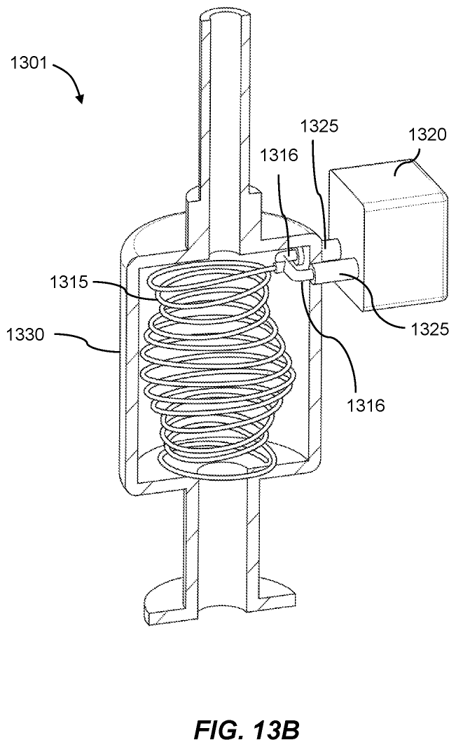

FIGS. 13A and 13B are detailed sectional views of gas heaters with different types of resistive heating elements that may be used in embodiments of the internal bake systems of the present disclosure. FIG. 13A shows a gas heater 1300 with a resistive heating element 1310 inside a housing 1330. The resistive heating element 1310 is configured as a coil in the shape of a cylinder having a constant diameter along its length. Ends 1311 of the resistive heating element 1310 are electrically connected to terminals 1325 of PID controller 1320 so that PID controller 1320 can adjust the electrical current flowing through resistive heating element 1310, consequently adjusting the amount of heat transferred to a gas flowing through gas heater 1300.

FIG. 13B is a detailed sectional view depicting a gas heater 1301 with a different type of resistive heating element 1315 inside housing 1330, where resistive heating element 1315 is a coil with varying diameter along its length. Ends 1316 of the resistive heating element 1315 are electrically connected to the terminals 1325 of PID controller 1320. This configuration of varying diameter may enhance heating of the gas by, for example, placing more coils in the path of the gas flow and/or creating turbulence.

The various embodiments of components disclosed herein may be used interchangeably with each other. For example, one or more injector tubes (e.g., FIGS. 5A-5C and 6A-6C) may or may not be included with the various embodiments disclosed herein. In other examples, one or more features chosen from multiple gas heaters (e.g., FIGS. 7A-7C), a helical path within the cryopanel (FIGS. 8A-8B), a cryopanel with an aperture aligned with the vacuum pump (FIGS. 9A-9C), a regenerative flow arrangement (FIG. 12), or different resistive heating elements of the gas heater (FIGS. 13A-13B) may be used in various combinations with each other for the internal bake systems for outgassing a material deposition system.

In aspects in accordance with the present disclosure, a material deposition system comprises a growth chamber configured for a vacuum environment. The material deposition system may be, for example, an ultra-high vacuum molecular beam epitaxy system. A fluid circulation panel is inside the growth chamber, spaced apart from an inner surface of the growth chamber and comprising walls around an interior of the fluid circulation panel. A first port is in communication with the interior of the fluid circulation panel. A first gas heater is coupled to the first port to heat and supply a heated gas into the interior of the fluid circulation panel to heat the walls of the fluid circulation panel.

In some examples, the fluid circulation panel is configured to be heated by the heated gas to outgas or desorb the inner surface of the growth chamber and the walls of the fluid circulation panel. The fluid circulation panel may be a cryopanel, a cryoshroud, a source cooling panel, a drip pan, or other vessel or housing in the growth chamber through which liquid and/or gas can circulate.

In some examples, an injector pipe is inserted into the interior of the fluid circulation panel through the first port, the injector pipe configured to inject the heated gas at a plurality of locations in the interior of the fluid circulation panel. For example, the injector pipe may comprise a plurality of holes along a length of the injector pipe, where holes of the plurality of holes vary in size or shape along the length of the injector pipe. The injector pipe may have a length that extends along a height (e.g., approximately a full height) of the fluid circulation panel.

In some examples, a second gas heater is coupled to a second port, wherein the second port is in communication with the interior of the fluid circulation panel.

In some examples, the fluid circulation panel has an annular cylindrical shape, and in further examples a helical rib is in the interior of the fluid circulation panel.

In some examples, the fluid circulation panel further comprises an aperture through at least one of the walls of the fluid circulation panel. A vacuum pump is coupled to the growth chamber, and the vacuum pump is aligned with the aperture such that the vacuum pump has a line of sight to a central region of the growth chamber, the central region being surrounded by the fluid circulation panel.

In some examples, the material deposition system includes a control system in communication with i) a flow rate monitor coupled to the first gas heater and/or ii) a first temperature sensor at an outlet end of the first gas heater. The control system may be in communication with a second temperature sensor and/or a pressure sensor, the second temperature sensor and/or the pressure sensor being located in the growth chamber.

In some aspects of the present disclosure, an apparatus for internally heating a material deposition system (e.g., a molecular beam epitaxy system) for equipment maintenance includes a fluid circulation panel and a gas heater coupled to the fluid circulation panel. The fluid circulation panel may be a cryopanel, a cryoshroud, a source cooling panel, a drip pan, or other vessel or housing within a growth chamber of the material deposition system through which liquid or gas can circulate. The gas heater is configured to supply a heated gas into an interior of the fluid circulation panel to heat the walls of the fluid circulation panel. The apparatus may include features as described through this disclosure, such as an injector pipe, an aperture through a wall of fluid circulation panel, a control system in communication with the gas heater, and/or multiple gas heaters.

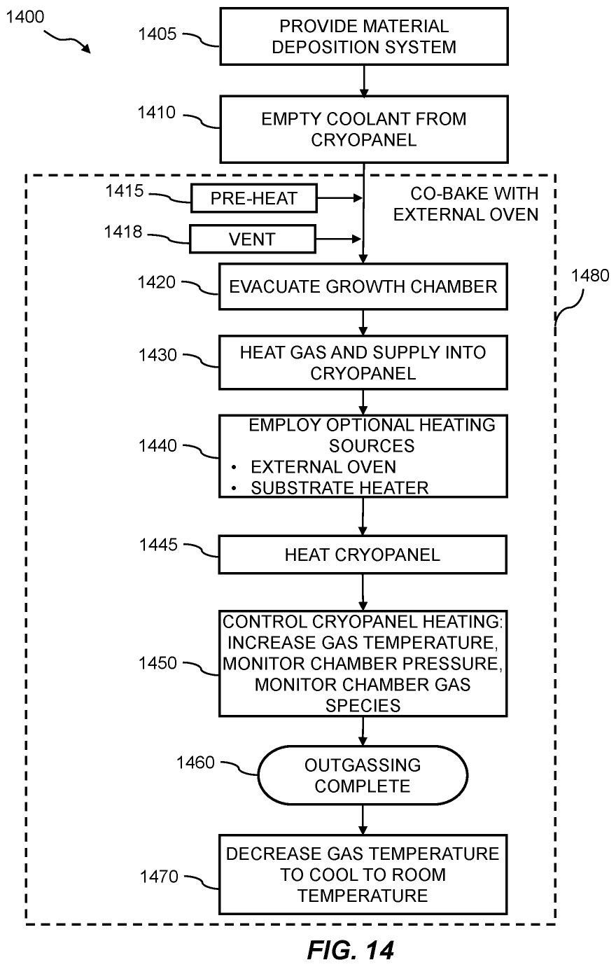

FIG. 14 is a flow diagram of a method 1400 for performing equipment maintenance involving outgassing (e.g., desorbing water and/or other substances as described in FIG. 2) a high vacuum growth chamber (e.g., operating at pressures less than 5×10⁻⁴ Torr) of a material deposition system, such as an ultra-high vacuum molecular beam epitaxy system, in accordance with embodiments. In some cases, the internal bake processes of the present disclosure may be utilized for short preventative maintenance campaigns, such as a source replacement and/or limited number of source refills.

In block 1405 a material deposition system is provided, the system having a vacuum growth chamber. In some examples, the material deposition system is an ultra-high vacuum molecular beam epitaxy system. The material deposition system also includes a cryopanel, a first port, and a first gas heater. The cryopanel is inside the growth chamber and spaced apart from an inner surface of the growth chamber, the cryopanel comprising walls around an interior of the cryopanel. The first port is in communication with the interior of the cryopanel. The first gas heater is coupled to the first port to heat and supply a gas into the interior of the cryopanel.

Once vented, the chamber has the machine in a state comprising all the source cells being unpowered, and the substrate heater being unpowered. In block 1410 of method 1400, coolant is completely removed from the cryopanel, and all water lines for the specific module are purged. The coolant may be, for example, LN₂ or water. The He-cryopumps are valved OFF and ideally have been regenerated using a heated blanket method. This removes all water and aids in desorption of hydrogen from the charcoal adsorber.

To begin the internal bake, block 1420 involves evacuating the growth chamber to a vacuum pressure of at least 1×10⁻⁸ Torr. The growth chamber is first sealed and evacuated in block 1420 using, for example, a Venturi pump to bring the chamber immediately below atmospheric. The chamber is then pumped via a dry pump until <100 mTorr is achieved. A turbo pump can then be used to bring the system vacuum down to 1×10⁻⁵ Torr to 1×10⁻⁶ Torr upon which the high pumping speed of the He-cryopumps can be implemented. Once a chamber vacuum of less than 1×10⁻⁸ Torr is achieved, such as approaching 1×10⁻⁹ Torr in some embodiments, the long pumping tail due to water desorption can comprise approximately 85% of the volatile species being pumped and limit the ultimate vacuum. In an example embodiment, a vacuum of approximately 5×10⁻⁹ Torr may be achieved, as limited by water desorption.

In block 1430, heated gas is injected into the cryopanel to begin heating the growth chamber. Block 1430 involves heating the gas with the first gas heater and supplying the gas into the interior of the cryopanel. The injected gas is supplied by a gas heater through a port connected to the cryopanel, as described herein (e.g., FIGS. 4A-4D). The material deposition system may include features described herein, such as injector tubes, multiple gas heaters, a helical path within the cryopanel, a cryopanel with an aperture aligned with the vacuum pump, a regenerative flow arrangement, and/or different resistive heating elements in the gas heater.

Block 1440 involves optionally heating at least one of a substrate heater or a material source heater, where the substrate heater is located in the growth chamber and the material source heater is coupled to the growth chamber. Block 1440 involves employing optional heating sources such as the substrate heater 145 of FIG. 4C or an external oven 495 of FIG. 4D (as shall be described for block 1480) which may be performed before, after or simultaneously with block 1430. The optional heating sources may reduce the time for the cryopanel and growth chamber to achieve the desired outgassing temperature.

In block 1440, in a controlled and sequential manner, the material sources are optionally ramped up slowly to approximately 200-300° C. depending upon the material within the source. For example, Mg and Zn can be ramped to only around 125° C. to prevent water accumulation. The substrate heater can then be ramped to approximately 400-450° C. In some cases, the chamber vacuum, during outgassing of the cells and substrate heater, will not exceed 1×10⁻⁷ Torr and preferably not exceed 5×10⁻⁸ Torr. This is because of the multiple baffles and indirect line of sight pumping presented to outgassing species. Once the chamber has achieved the desired vacuum level (e.g., <5×10⁻⁸ Torr), a helium leak check can be performed, and action taken to remedy any leaks.

In an example where block 1440 is performed before block 1430, when all the available internal heat load provided by the sources and substrate heater have stabilized and the chamber pressure is below 5×10⁻⁸ Torr, then in block 1430 the heated gas (e.g., nitrogen or argon) is introduced into the cryopanel and any other fluid circulation panels being used as a heating source. In embodiments, various internal panels of the deposition system may have heated gas injected into them, such as one or more of the LN₂ cryopanel, a source water cooling panel, and a drip pan. The heated gas may be regulated in temperature, monitored via an internal temperature sensor (e.g., thermocouple) on the gas heater or via other temperature sensors located in the outlet flow path of the gas heater. In some embodiments in which two growth chambers are included in an MBE system, and one growth chamber may be worked on while the other is left fully operating.

The heat introduced in blocks 1430 and 1440 results in heating of the cryopanel in block 1445, using the gas supplied to the interior of the cryopanel to outgas the inner surface of the growth chamber and the walls of the cryopanel.

Block 1450 involves controlling, using a control system, the heating of the cryopanel to raise a temperature of the inner surface of the growth chamber at a desired rate. In embodiments, block 1450 includes controlling, using a control system, a flow rate and a temperature of the gas using information from: a flow rate monitor coupled to the first gas heater; a first temperature sensor at an outlet end of the gas heater; a second temperature sensor located in the growth chamber; and a pressure sensor located in the growth chamber.

During block 1450 the temperature of the gas being injected into the cryopanel is increased, and the growth chamber pressure and growth chamber gas species are monitored. The gas flow rate and gas heater temperature (e.g., as measured by an internal thermocouple in the gas heater) are adjusted by a control system to obtain a desired rate of temperature rise of the internal inner surfaces (i.e., walls) of the growth chamber. The temperature of the growth chamber can be raised at a rate of, for example, approximately 0.5° C./minute (° C./min) to approximately 20° C./min. In embodiments, temperature ramp rates of, for example, 1° C./min to 2.5° C./min, or 1° C./min to 5° C./min, or 2° C./min to 5° C./min, or 1° C./min to 20° C./min, or greater than 1° C./min, greater than 2° C./min, greater than 5° C./min, or greater than 20° C./min can be achieved. These temperature ramp rates of the growth chamber, produced by the internal heating systems and methods of the present disclosure, are faster than those that can be achieved by conventional bake methods, which are typically limited to less than 1° C./min. Thus, the present systems and methods can significantly improve production rates and decrease maintenance costs of a material deposition system by decreasing the downtime required for maintenance. In some cases, the ramp rate may be controlled to achieve a gradual rise in temperature in case rapid increases in chamber pressures occur. For example, the method may involve controlling, using a control system, the heating of the cryopanel to raise a temperature of the inner surface of the growth chamber at a rate of less than or equal to 5° C./minute, or less than or equal to 10° C./minute.

The temperature ramp rates achievable by the present systems and methods are greater than the rates of <0.5° C./min that are achieved by conventional external bake processes, thus demonstrating the immense reduction in maintenance time that is possible with the present embodiments. These ramp rates are possible because of the heat being introduced within the growth chamber, rather than heat from an external oven needing to be transferred through the walls of the growth chamber. Additionally, the internal bake process does not require the disconnection of various lines to the growth chamber as is needed for implanting an external oven around the growth chamber as in conventional methods. Utilization of the existing cryopanel or other fluid circulation panels of the material deposition system also avoids introducing new contaminants into the system, as can occur with bakeout lamps inside the reaction chamber as have been used in the prior art.

During the outgassing procedure of method 1400, the material sources and substrate heater can remain at the internal bake setpoints. If solid source cells allow raising of the temperature beyond approximately 200-250° C. this may beneficially add to the internal heat loading. In some cases, material source shutters are cycled periodically during and after the main outgassing event performed by the cryopanel.

In block 1450, the chamber pressure can also be monitored, such as by a pressure sensor located in the growth chamber. The rate of temperature rise of the growth chamber can be balanced with pressure because if the temperature rises too fast (e.g., straight to a Tₘₐₓ of 200° C.), then the increase in partial pressure of H₂O caused by the rapid desorption from surfaces of the growth chamber and cryopanel can potentially overload the vacuum pump. In embodiments, the pressure in the growth chamber may be maintained at a level less than approximately 5×10⁻⁸ Torr during block 1450. Higher pressures, for example 1×10⁻⁷ Torr, can also disadvantageously result in the H₂O molecules redepositing on the surfaces.

The onset of outgassing of water from the in vacuo surfaces will generally begin at ˜80° C. and peak toward 100° C. thereby causing a rise in chamber pressure. An overshoot of ˜125° C. is desirable, with a temperature of less than 200° C. being the upper limit. Once the chamber pressure peaks (e.g., up to approximately 5×10⁻⁸ Torr) and then begins to drop, this provides direct evidence that the internally heated surfaces are outgassed. Block 1460 indicates the completion of outgassing. Once the chamber pressure has subsided to 5×10⁻⁸ Torr or below, the gas heaters are gradually reduced in temperature in block 1470 to cool the growth chamber to room temperature.

After the internal bake method 1400 has been completed, water flow can then be reestablished to components of the material deposition system such as the source cells, drip pan and source cooling panels. Lastly, the coolant circuit (e.g., LN₂) to the cryopanel can be reestablished. The coolant should be reconnected to the cryopanel only after sufficient time is allowed for the cryopanel temperature to stabilize after the heated gas (e.g., N₂) flow has been ended. Typically, as the cryopanel is filled with LN₂, the chamber vacuum is reduced, followed by a rapid reduction in chamber vacuum as the LN₂ boils off. The chamber pressure may then stabilize at a slightly higher pressure once the cryopanel has completely filled and stabilized to 77 K. Once the system has stabilized, conventional protocols for source high temperature and substrate heater outgassing may proceed.

During the venting process of the growth chamber the cryopanel will attain a temperature that is ideally higher than the dew point of water. As the cryopanel is essentially in a “thermos flask,” it takes a considerable amount of time for the panel to reach this point, such as on the order of two days. That is, it can take significant time after purging the cryopanel from LN₂ for the temperature of the cryopanel to reach 300 K. A cold cryopanel during venting will exacerbate water accumulation. To overcome this issue, some embodiments include optional block 1415 of pre-heating the cryopanel (e.g., to 25-30° C.) before evacuating the growth chamber and prior to venting in block 1418, thus preventing a large amount of water from accumulating. That is, some embodiments involve venting the growth chamber after the pre-heating and before the evacuating, to reduce the amount of water that accumulates on the cryopanel. The pre-heating may be achieved by supplying heated gas from the gas heater and/or by using other heating sources such as a substrate heater or material source heater. This pre-heating, such as to at least room temperature can improve pump down times and reduce the soak time for bakeout. In embodiments of block 1415, the pre-heating comprises pre-heating the cryopanel to an ambient temperature.

Some embodiments may also optionally include block 1480 of co-baking the growth chamber with an external oven while supplying the gas. The co-bake process incorporates an external oven to heat the growth chamber while blocks 1420 to 1470 (and optionally blocks 1415 and 1418) are performed for the internal bake procedure. The co-baking of block 1480 can reduce the thermal budget required by the external oven. In such embodiments, the temperature of the internal surfaces of the UHV reactor can attain a higher in vacuo wall temperature and be more efficient at outgassing water than using an external oven alone.

FIG. 15 shows a block diagram 1500 of operation of a control system (e.g., control system 490 of FIG. 4A) for implementing the internal bake procedure for outgassing a material deposition system, in accordance with embodiments. As described above, the sequence, timing and parameters for the various steps of the internal bake process must be carefully controlled to achieve proper outgassing and avoid component failures. Diagram 1500 represents steps involved with block 1450 of FIG. 14.

In block 1510, the control system receives an initial temperature “Tᵢₙᵢₜ”, a desired temperature increment “ΔT”, a maximum temperature “Tₘₐₓ” for the growth chamber, and a time duration “Δt” as inputs. Tᵢₙᵢₜ is an initial set temperature for the gas being output by the gas heater. Tₘₐₓ is the target temperature for the growth chamber to reach for the outgassing process. In block 1520, the system sets a value “T1”—a temporary target temperature of the gas being output by the gas heater—equal to Tᵢₙᵢₜ.

In block 1530, a set temperature of the gas heater “T_{Hset}” is given a value equal to T1. The loop 1565 from block 1530 to block 1570 increases the temperature of the growth chamber gradually, in increments according to ΔT, to avoid the chamber pressure from exceeding desired limits. The value of ΔT may be set to achieve desired temperature ramp rates as described herein. In block 1540, the growth chamber pressure is monitored while the cryopanel is heated by gas supplied by the gas heater. If the chamber pressure is greater than a threshold pressure P_{Threshold}, such as 5×10⁻⁸ Torr, that indicates that the temperature is too high in block 1545. The control system then pauses on heating the cryopanel further (e.g., adjusts the heating of the cryopanel by stopping increasing the gas temperature), waiting as indicated by loop 1548 until the chamber pressure reduces. If in block 1540 the chamber pressure is less than 5×10⁻⁸ Torr, the method proceeds to block 1550 in which the growth chamber is soaked at a heated temperature for a time duration Δt. The time duration is determined by the temperature ramp rate and the amount of time elapsed (if any, per loop 1548) while waiting for the chamber pressure to reduce.

In block 1560, the temporary target temperature T1 is incremented by the amount ΔT. In block 1570, if this new value of T1 (previous T1 plus ΔT) is not greater than the desired chamber temperature Tₘₐₓ, then loop 1565 resets the heater set temperature T_{Hset} to the new value of T1 from block 1560, and the heater will continue to heat the gas. If the value of T1 in block 1560 has reached at least the desired chamber temperature Tₘₐₓ (i.e., T1≥Tₘₐₓ), then in block 1580 the growth chamber is soaked at the desired temperature until the chamber pressure is reduced to less than 1×10⁻⁹ Torr, which indicates that sufficient desorption has occurred.

As indicated in block 1450, of FIG. 14, the chamber gas species are also monitored during the outgassing process. FIG. 16 is a simplified plot 1600 of the variation in partial pressure of H₂O (dominant gas—18 atomic mass units “amu”) as a function of time during outgassing (e.g., desorption) with an internal bake process (e.g., during one iteration of loop 1565 of FIG. 15), as measured by a residual gas analyzer (RGA). Also shown is a plot 1650 of the corresponding temperature of the growth chamber as a function of time. These plots show that as the chamber temperature ramps up it will eventually reach a point (indicated at time t1) where the desorption of H₂O will cause the pressure in the chamber to increase. The control system, as described in relation to FIG. 15, then stops increasing the gas temperature (e.g., lowers the gas temperature and/or flow rate) as otherwise, the H₂O desorption will overload the pump. Time t2 is a peak measured in partial pressure of water, and between times t2 and t3 the water is desorbed from the surface (at the soak temperature T1). If the temperature is held constant at T1 after time t2, as shown in the figure, then the water will continue to be desorbed as indicated by the water partial pressure decreasing between t2 and t4 in the figure. The time period from t1 to t3 in FIG. 16 is an example of block 1545 and loop 1548 of FIG. 15, where the control system waits while the chamber pressure reduces to below the threshold pressure P_{Thr}. In other embodiments, P_{Thr} can have a value higher than illustrated. The growth chamber is soaked at a heated temperature during time 0 to t4, which corresponds to time duration Δt in block 1550 of FIG. 15.

These temperature and pressure trends represented by FIG. 16 are repeated as loop 1565 is repeated with increasing values of T1, until the desired final outgassing temperature Tₘₐₓ is reached. For example, in some cases (not shown in FIG. 16), at time t3 (i.e., after the partial pressure of water falls below the threshold pressure “P_{Thr}”), the temperature can be increased to a temperature T2 (higher than T1, where T1 is incremented by ΔT per block 1560 in FIG. 15) and then held at T2 for some period of time. The increase in temperature to T2 can cause additional water to desorb, and the partial pressure of water would again increase while the temperature is held at T2. This cycle can then be repeated (e.g., as described in method 1500 in FIG. 15) until a sufficient amount of water is desorbed from the material deposition system, and/or until a maximum temperature Tₘₐₓ is reached. For example, the temperature T1 may be increased in a stepped fashion (in loop 1565 of FIG. 15) until Tₘₐₓ is reached, waiting between each temperature increase for the pressure to spike and then decrease. After the maximum temperature has been reached, the system can be held at that temperature (per block 1580 of FIG. 15) until the measured partial pressure of water peaks and then falls below Pₜₕᵣ, and the total chamber pressure falls below a final pressure (e.g., less than 1×10⁻⁸ Torr or less than 1×10⁻⁹ Torr). After soaking at Tₘₐₓ in block 1580 (i.e., when T1≥Tₘₐₓ), the outgassing procedure is completed with the gas heating being gradually turned off.

In some embodiments, the control system uses a temperature sensor in the gas heater (e.g., at an outlet of the gas heater) to measure the temperature of the heated gas. In other embodiments, multiple temperature sensors can also be in communication with the control system, such as in the cryopanel and/or growth chamber, to further enhance the ability to provide uniform heating of the cryopanel and growth chamber. It is desirable to have uniform heating, in particular on the interior surface of the cryopanel (i.e., surface of inner wall 935 enclosing central region 915 of the growth chamber and surrounding the substrate 140). Furthermore, multiple temperature sensors can be used within the cryopanel and/or the growth chamber to check that individual locations on the outgassing surfaces have reached the desired temperature. In some embodiments, feedback from multiple temperature sensors can be used to provide regional control of individual gas heaters, if multiple gas heaters are being used, to prevent cold spots or temperature gradients that could cause moisture to be redeposited on the surfaces.

In aspects in accordance with the present disclosure, methods of performing maintenance of a material deposition system comprise evacuating a growth chamber of the material deposition system to a vacuum pressure of at least 1×10⁻⁸ Torr. The material deposition system comprises the growth chamber, wherein the growth chamber is configured for a vacuum environment. The material deposition system also includes a fluid circulation panel inside the growth chamber and spaced apart from an inner surface of the growth chamber, the fluid circulation panel comprising walls around an interior of the fluid circulation panel; a first port in communication with the interior of the fluid circulation panel; and a gas heater coupled to the first port to heat and supply a gas into the interior of the fluid circulation panel. The method includes heating the gas with the gas heater. After the heating of the gas, the gas is supplied into the interior of the fluid circulation panel. The fluid circulation panel is heated, using the gas supplied to the interior of the fluid circulation panel.

In some examples, the heating of the fluid circulation panel causes outgassing of the inner surface of the growth chamber and of the walls of the fluid circulation panel. In some examples, the fluid circulation panel is a cryopanel, a cryoshroud, a source cooling panel, a drip pan, or other vessel or housing in the growth chamber through which liquid or gas can circulate.

In some examples, supplying the gas comprises supplying the gas through an injector pipe inserted into the interior of the fluid circulation panel through the first port. The injector pipe is configured to inject heated gas at a plurality of locations in the interior of the fluid circulation panel.

In some examples, the methods include heating at least one of a substrate heater or a material source heater, wherein the substrate heater is located in the growth chamber, and the material source heater is located in or coupled to the growth chamber.

In some examples, the methods include co-baking the growth chamber with an external oven while supplying the gas. In some examples, the methods include pre-heating the fluid circulation panel before evacuating the growth chamber. Certain examples include venting the growth chamber after the pre-heating and before the evacuating, to reduce an amount of water that accumulates on the fluid circulation panel. In certain examples, the pre-heating comprises pre-heating the fluid circulation panel to an ambient temperature.

In some examples, the methods include controlling, using a control system, the heating of the fluid circulation panel to raise a temperature of the inner surface of the growth chamber at a rate of greater than or equal to 1° C./minute, such as greater than 2° C./minute, or greater than 3° C./minute, or greater than 5° C./minute, or from 1° C./minute to 20° C./minute.

In some examples, the methods include controlling, using a control system, a flow rate and a temperature of the gas using information from: a flow rate monitor coupled to the gas heater; a first temperature sensor at an outlet end of the gas heater; a second temperature sensor located in the growth chamber; and a pressure sensor located in the growth chamber. In certain examples, the controlling comprises adjusting the heating of the fluid circulation panel when a pressure in the growth chamber, as measured by the pressure sensor, exceeds a threshold pressure. In certain examples, the controlling comprises reducing the temperature of the gas after a pressure inside the growth chamber has peaked.

Advantages of the internal bake systems and methods of the present disclosure include providing a fast turnaround from venting a UHV chamber to the re-establishment of UHV conditions. Also, isolating a single growth chamber using the present techniques allow preventative maintenance to be performed with greater flexibility in the production schedule. Embodiments beneficially utilize existing fluid circulation panels (e.g., cryopanel) of a material deposition system (e.g., high vacuum or ultra-high vacuum molecular beam epitaxy system) in a new way, where the fluid circulation pane(s) serve as a heating source to more efficiently and cost-effectively perform equipment maintenance of the material deposition system compared to conventional techniques. Additional features such as injector tubes, inclusion of multiple gas heaters, gas heater coil designs, features within the cryopanel interior to distribute gas flow, alignment of a cryopanel aperture with the vacuum pump, and control systems and methods for controlling operation of the internal bake procedures are also disclosed that even further improve the performance of the present embodiments.

Reference has been made in detail to embodiments of the disclosed invention, one or more examples of which have been illustrated in the accompanying figures. Each example has been provided by way of explanation of the present technology, not as a limitation of the present technology. In fact, while the specification has been described in detail with respect to specific embodiments of the invention, it will be appreciated that those skilled in the art, upon attaining an understanding of the foregoing, may readily conceive of alterations to, variations of, and equivalents to these embodiments. For instance, features illustrated or described as part of one embodiment may be used with another embodiment to yield a still further embodiment. Thus, it is intended that the present subject matter covers all such modifications and variations within the scope of the appended claims and their equivalents. These and other modifications and variations to the present invention may be practiced by those of ordinary skill in the art, without departing from the scope of the present invention, which is more particularly set forth in the appended claims. Furthermore, those of ordinary skill in the art will appreciate that the foregoing description is by way of example only and is not intended to limit the invention.

What is claimed is:

1. A material deposition system comprising:
a growth chamber configured for a vacuum environment;
a fluid circulation panel inside the growth chamber and spaced apart from an inner surface of the growth chamber, the fluid circulation panel comprising walls around an interior of the fluid circulation panel;
a first port in communication with the interior of the fluid circulation panel;
a first gas heater coupled to the first port, the first gas heater configured to supply a heated gas; and
an injector pipe inserted through the first port and into the interior of the fluid circulation panel, the injector pipe configured to inject the heated gas at a plurality of locations in the interior of the fluid circulation panel to heat the walls of the fluid circulation panel, such that the heated walls of the fluid circulation panel heat the inner surface of the growth chamber.

2. The system of claim 1, wherein the fluid circulation panel is configured to be heated by the heated gas to serve as a heating source for performing internal bakeout of the inner surface of the growth chamber.

3. The system of claim 1, wherein the fluid circulation panel is a cryopanel.

4. The system of claim 1, wherein the injector pipe comprises a plurality of holes along a length of the injector pipe to inject the heated gas at the plurality of locations in the interior of the fluid circulation panel.

5. The system of claim 4, wherein holes of the plurality of holes vary in size along the length of the injector pipe.

6. The system of claim 4, wherein holes of the plurality of holes vary in shape along the length of the injector pipe.

7. The system of claim 4, wherein a spacing, a number, or a shape of the plurality of holes are configured to promote uniform heating of the fluid circulation panel.

8. The system of claim 1, wherein the injector pipe has a length that extends along a height of the fluid circulation panel.

9. The system of claim 1, further comprising a second gas heater coupled to a second port, wherein the second port is in communication with the interior of the fluid circulation panel, and the second gas heater is configured to supply the heated gas.

10. The system of claim 9, further comprising a second injector pipe inserted through the second port and into the interior of the fluid circulation panel, the second injector pipe configured to inject the heated gas at a second plurality of locations in the interior of the fluid circulation panel.

11. The system of claim 1, wherein the fluid circulation panel has an annular cylindrical shape.

12. The system of claim 1, further comprising a control system in communication with i) a flow rate monitor coupled to the first gas heater and ii) a first temperature sensor at an outlet end of the first gas heater.

13. The system of claim 12, wherein the control system is in communication with a second temperature sensor and a pressure sensor, the second temperature sensor and the pressure sensor being located in the growth chamber.

14. A material deposition system comprising:
a growth chamber configured for a vacuum environment;
a fluid circulation panel inside the growth chamber and spaced apart from an inner surface of the growth chamber, the fluid circulation panel comprising walls around an interior of the fluid circulation panel;
an injector pipe in the interior of the fluid circulation panel, the injector pipe comprising a plurality of holes along a length of the injector pipe; and
a first gas heater configured to supply a heated gas through the injector pipe and into the interior of the fluid circulation panel, to heat the walls of the fluid circulation panel such that the heated walls of the fluid circulation panel heat the inner surface of the growth chamber.

15. The system of claim 14, wherein the fluid circulation panel is configured to be heated by the heated gas to serve as a heating source for performing internal bakeout of the inner surface of the growth chamber.

16. The system of claim 14, further comprising a first port in communication with the interior of the fluid circulation panel, wherein the injector pipe is inserted through the first port, and the first gas heater is coupled to the first port.

17. The system of claim 14, wherein holes of the plurality of holes vary in size along the length of the injector pipe.

18. The system of claim 14, wherein holes of the plurality of holes vary in shape along the length of the injector pipe.

19. The system of claim 14, wherein a spacing, a number, or a shape of the plurality of holes are configured to promote uniform heating of the fluid circulation panel.

20. The system of claim 14, wherein the length of the injector pipe extends along a height of the fluid circulation panel.

21. The system of claim 14, further comprising:
a second gas heater in communication with the interior of the fluid circulation panel, the second gas heater configured to supply the heated gas; and
a second injector pipe in the interior of the fluid circulation panel, the injector pipe configured to inject the heated gas from the second gas heater at a second plurality of locations in the interior of the fluid circulation panel.
